(19) United States
(12) Patent Application Publication
(10) Pub. No.: US 2026/0269795 A1
(43) Pub. Date: Sep. 10, 2026

(54) Power Amplifier, Chip, RF Front-End Module, and Transformer Structure

(71) Applicant: RadRock (Chongqing) Tech Co., Ltd., Chongqing (CN)

(72) Inventors: Yuan Cao, Chongqing (CN); Xinghua Rong, Chongqing (CN); Zilin Liu, Chongqing (CN); Jianxing Ni, Chongqing (CN)

(21) Appl. No.: 19/663,504

(22) Filed: Apr. 30, 2026

Related U.S. Application Data
(63) Continuation of application No. PCT/CN2024/128326, filed on Oct. 30, 2024.

(30) Foreign Application Priority Data
Oct. 31, 2023 (CN) 202311432064.4

(51) Int. Cl. H03F 3/24

(52) U.S. Cl. CPC H03F 3/245; H03F 2200/06; H03F 2200/09; H03F 2200/451

(57) ABSTRACT

Disclosed are a power amplifier, a chip, an RF front-end module, and a transformer structure. The power amplifier includes first and second power amplification circuits, and a balun. The first and second power amplification circuits are respectively connected to the balun. The balun includes a primary coupling line including first and second input terminals, and a secondary coupling line including first and second output terminals. A first routing path of the primary coupling line follows a second routing path of the secondary coupling line. The first routing path is a routing path from the first to the second input terminal; the second routing path is a routing path from the first to the second output terminal. Because the primary and secondary lines follow each other, the balun has a better coupling degree. Furthermore, shapes and positions of these lines can be adjusted flexibly, facilitating the miniaturization design of the module.

### CROSS REFERENCE TO RELATED APPLICATIONS

The present application is a Continuation Application of PCT Application No. PCT/CN2024/128326 filed on Oct. 30, 2024, which claims the benefit of Chinese Patent Application No. 202311432064.4 filed on Oct. 31, 2023. All the above are hereby incorporated by reference in their entirety.

### TECHNICAL FIELD

The present application relates to the technical field of radio frequency (RF), and more particularly, to a power amplifier, a chip, a radio frequency front-end module, and a transformer structure.

### BACKGROUND

RF power amplifiers are widely used in fields such as communications, broadcasting, radar, industrial processing, medical instrumentation, and scientific research. Currently, with the development of 5G communication systems, higher requirements have been placed on RF power amplifiers, such as meeting the needs for higher frequencies and higher-order QAM (Quadrature Amplitude Modulation).

In RF power amplifiers, impedance matching is a crucial component. Transformers are typically utilized to perform impedance matching for the input or output of the RF power amplifier. However, traditional transformer structures usually occupy a large area, which is disadvantageous for the miniaturization design of RF front-end modules.

### SUMMARY OF THE APPLICATION

This application provides a power amplifier, a chip, an RF front-end module, and a transformer structure capable of reducing an area occupied by the power amplifier, which facilitates miniaturization design of the RF front-end module.

In a first aspect, an embodiment of this application provides a power amplifier including a first power amplification circuit, a second power amplification circuit, and a balun. The first power amplification circuit and the second power amplification circuit are respectively connected to the balun. The balun includes: a primary coupling line including a first input terminal and a second input terminal; and a secondary coupling line including a first output terminal and a second output terminal. A first routing path of the primary coupling line follows a second routing path of the secondary coupling line. The first routing path is a routing path from the first input terminal to the second input terminal, and the second routing path is a routing path from the first output terminal to the second output terminal.

In a second aspect, an embodiment of this application provides a chip including at least one power amplifier. The power amplifier includes a first power amplification circuit, a second power amplification circuit, and a balun. The first power amplification circuit and the second power amplification circuit are respectively connected to the balun. The balun includes: a primary coupling line including a first input terminal and a second input terminal; and a secondary coupling line including a first output terminal and a second output terminal. A first routing path of the primary coupling line follows a second routing path of the secondary coupling line. The first routing path is a routing path from the first input terminal to the second input terminal, and the second routing path is a routing path from the first output terminal to the second output terminal.

In a third aspect, an embodiment of this application provides an RF front-end module including: a substrate; a power amplification chip disposed on the substrate; and a balun disposed on the substrate and connected to the power amplification chip. The balun includes: a primary coupling line including a first input terminal and a second input terminal; and a secondary coupling line including a first output terminal and a second output terminal. A first routing path of the primary coupling line follows a second routing path of the secondary coupling line. The first routing path is a routing path from the first input terminal to the second input terminal, and the second routing path is a routing path from the first output terminal to the second output terminal.

In a fourth aspect, an embodiment of this application provides a transformer structure including: a primary coupling line including a first input terminal and a second input terminal; and a secondary coupling line including a first output terminal and a second output terminal. A first routing path of the primary coupling line follows a second routing path of the secondary coupling line. The first routing path is a routing path from the first input terminal to the second input terminal, and the second routing path is a routing path from the first output terminal to the second output terminal.

According to the first to fourth aspects of the embodiments of this application, because the routing paths of the primary coupling line 201 and the secondary coupling line 202 of the balun/transformer structure from a starting point to an ending point follow each other, every segment of the primary coupling line can couple with a corresponding segment of the secondary coupling line. Conversely, every segment of the secondary coupling line can also couple with a corresponding segment of the primary coupling line, resulting in a better coupling degree. Furthermore, the shapes and arrangement positions of the primary coupling line 201 and the secondary coupling line 202 of the transformer structure/balun can be flexibly set to adapt to the layout of other circuits in the power amplifier. This makes the overall structure of the power amplifier more compact, thereby reducing the area occupied by the power amplifier and facilitating the miniaturization design of the RF front-end module.

According to the first to fourth aspects of the embodiments of this application, because the routing paths of the primary coupling line and the secondary coupling line of the balun/transformer structure from a starting point to an ending point follow each other, every segment of the primary coupling line can couple with a corresponding segment of the secondary coupling line. Conversely, every segment of the secondary coupling line can also couple with a corresponding segment of the primary coupling line, resulting in a better coupling degree. Furthermore, the shapes and arrangement positions of the primary coupling line and the secondary coupling line of the transformer structure/balun can be flexibly set to adapt to the layout of other circuits in the power amplifier. This makes the overall structure of the power amplifier more compact, thereby reducing the area occupied by the power amplifier and facilitating the miniaturization design of the RF front-end module.

### BRIEF DESCRIPTION OF THE DRAWINGS

To provide a clearer illustration of technical solutions in the embodiments of this application, the drawings required for the description are briefly introduced below. It is apparent that the drawings described below represent only some embodiments of this application. Based on these drawings, those skilled in the art can derive other drawings without creative effort.

FIG. 1 shows a structural schematic diagram of a transformer structure provided by related art.

FIG. 2 shows a structural schematic diagram of a transformer structure provided by an embodiment of this application.

FIG. 3 shows a structural schematic diagram of a transformer structure provided by another embodiment of this application.

FIG. 4 shows a structural schematic diagram of a transformer structure provided by yet another embodiment of this application.

FIG. 5 shows a structural schematic diagram of a transformer structure provided by yet another embodiment of this application.

FIG. 6 shows a structural schematic diagram of a transformer structure provided by yet another embodiment of this application.

FIG. 7 shows a structural schematic diagram of a power amplifier provided by an embodiment of this application.

FIG. 8 shows a structural schematic diagram of a power amplifier provided by another embodiment of this application.

FIG. 9 shows a structural schematic diagram of a power amplifier provided by yet another embodiment of this application.

FIG. 10 shows a structural schematic diagram of a power amplifier provided by yet another embodiment of this application.

FIG. 11 shows a layout schematic diagram of a primary coupling line and a secondary coupling line provided by an embodiment of this application.

FIG. 12 shows a layout schematic diagram of a primary coupling line and a secondary coupling line provided by another embodiment of this application.

FIG. 13 shows a structural schematic diagram of a power amplifier provided by yet another embodiment of this application.

FIG. 14 shows a structural schematic diagram of a power amplifier provided by yet another embodiment of this application.

FIG. 15 shows a structural schematic diagram of a power amplifier provided by yet another embodiment of this application.

FIG. 16 shows a structural schematic diagram of a power amplifier provided by yet another embodiment of this application.

FIG. 17 shows a structural schematic diagram of a power amplifier provided by yet another embodiment of this application.

FIG. 18 shows a structural schematic diagram of a power amplifier provided by yet another embodiment of this application.

FIG. 19 shows a structural schematic diagram of a chip provided by an embodiment of this application.

FIG. 20 shows a structural schematic diagram of a chip provided by another embodiment of this application.

FIG. 21 shows a structural schematic diagram of a chip provided by yet another embodiment of this application.

FIG. 22 shows a structural schematic diagram of an RF front-end module provided by an embodiment of this application.

### DETAILED DESCRIPTION OF EMBODIMENTS

To enable those skilled in the art to better understand the solutions of this application, technical solutions in embodiments of this application are described clearly and completely below in conjunction with the drawings. It is apparent that the described embodiments represent only some, rather than all, of the embodiments of this application. All other embodiments obtained by those skilled in the art based on the embodiments in this application without creative effort fall within the protection scope of this application.

Terms such as “first” and “second” in this application are used to distinguish between different objects rather than to describe a specific order. In addition, the terms “comprise” and “have,” along with any variations thereof, are intended to cover non-exclusive inclusions. For example, a process, method, system, product, or device including a series of steps or units is not limited to those listed; instead, it optionally further includes steps or units that are not listed, or optionally further includes other steps or units inherent to such a process, method, product, or device.

Reference herein to an “embodiment” means that a specific feature, structure, or characteristic described in connection with the embodiment can be included in at least one embodiment of this application. Occurrences of this phrase in various places in the specification do not necessarily refer to the same embodiment, nor are they independent or alternative embodiments that are mutually exclusive with other embodiments. It is understood, both explicitly and implicitly by those skilled in the art, that the embodiments described herein can be combined with other embodiments.

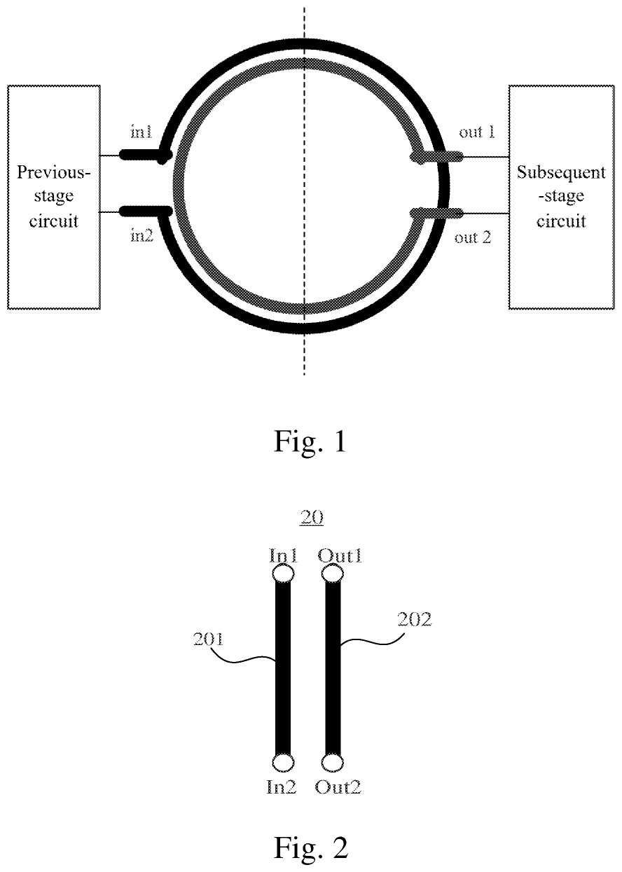

A transformer is a device that uses the principle of electromagnetic induction to change alternating current (AC) voltage, typically including a primary coil and a secondary coil. In a power amplifier, a transformer can also be used for impedance matching. In related art, as shown in FIG. 1, a primary coil includes two input ports in1 and in2, and a secondary coil includes two output ports out1 and out2. The input ports in1 and in2 of the primary coil are generally arranged near a previous-stage circuit, while the output ports out1 and out2 of the secondary coil are arranged near a subsequent-stage circuit to facilitate the connection between the primary coil and the previous-stage circuit, and the connection between the secondary coil and the subsequent-stage circuit. Related art typically winds a primary coil and a secondary coil centered at a position between the previous-stage and subsequent-stage circuits, using one input or output port as a starting point and the other as an ending point. Consequently, the overall shape of the formed transformer is a nearly closed ring. Since the internal space of the ring is insufficient to accommodate the previous-stage or subsequent-stage circuits, these circuits can only be arranged respectively on two sides of the transformer. This leads to wasted internal space and causes the power amplifier as a whole to occupy a large area, which is disadvantageous for the miniaturization design of the RF front-end module. Additionally, a gap between the two input ports in1 and in2 of the primary coil cannot couple with the secondary coil, and a gap between the two output ports out1 and out2 of the secondary coil cannot couple with the primary coil, which affects the coupling degree of the transformer structure.

To this end, embodiments of this application provide a transformer structure, a power amplifier, and an RF front-end module, which can reduce the area occupied by the power amplifier and facilitate the miniaturization design of the RF front-end module.

Please refer to FIG. 2, which shows a transformer structure provided by an embodiment of this application. As shown in FIG. 2, the transformer structure 20 includes a primary coupling line 201 and a secondary coupling line 202. The primary coupling line 201 includes a first input terminal In1 and a second input terminal In2, and the secondary coupling line 202 includes a first output terminal Out1 and a second output terminal Out2. The primary coupling line 201 is an input stage of the transformer structure 20 and is configured to receive an RF input signal from a previous-stage circuit. The secondary coupling line 202 is an output stage of the transformer structure 20 and is configured to couple with the primary coupling line 201 to generate an RF signal and output the coupled RF signal to a subsequent-stage circuit.

In the embodiments of this application, a routing path of the primary coupling line 201 from the first input terminal In1 to the second input terminal In2 is referred to as a first routing path, and a routing path of the secondary coupling line 202 from the first output terminal Out1 to the second output terminal Out2 is referred to as a second routing path. The first routing path follows the second routing path. In other words, if the first input terminal In1 is taken as a starting point of the primary coupling line 201, the second input terminal In2 as an ending point of the primary coupling line 201, the first output terminal Out1 as a starting point of the secondary coupling line 202, and the second output terminal Out2 as an ending point of the secondary coupling line 202, then the primary coupling line 201 and the secondary coupling line 202 each have roughly the same direction and exhibit roughly the same shape from the starting point to the ending point.

In the embodiments of this application, “follow” means that each segment of the primary coupling line is roughly parallel to a corresponding segment of the secondary coupling line. For example, if the primary coupling line 201 and the secondary coupling line 202 are both in a straight-line shape or an arc-shape, the primary coupling line and the secondary coupling line are parallel to each other as a whole. If the primary coupling line 201 and the secondary coupling line 202 each include one or more bends, the primary coupling line 201 and the secondary coupling line 202 can be respectively divided into multiple segments using each bending point as a boundary, such that each segment of the primary coupling line 201 is roughly parallel to a corresponding segment of the secondary coupling line 202.

Since the paths of the primary coupling line 201 and the secondary coupling line 202 from the starting point to the ending point follow each other, every segment of the primary coupling line can couple with a corresponding segment of the secondary coupling line. Conversely, every segment of the secondary coupling line can also couple with a corresponding segment of the primary coupling line, providing a better coupling degree compared to the structure shown in FIG. 1.

On the other hand, because the primary coupling line 201 and the secondary coupling line 202 are coupled to each other, the distance between them is very small, and they follow each other. Therefore, the starting points of the primary coupling line 201 and the secondary coupling line 202 are close to each other, and the ending points are also close to each other. In other words, the first input terminal In1 of the primary coupling line 201 and the first output terminal Out1 of the secondary coupling line 202 are arranged close to each other, and the second input terminal In2 of the primary coupling line 201 and the second output terminal Out2 of the secondary coupling line 202 are arranged close to each other.

Based on this, the primary coupling line 201 and the secondary coupling line 202 of the transformer structure overall present a line-shaped structure. Their shapes and arrangement positions can be flexibly set to adapt to the layout of other circuits in the power amplifier. This makes the overall structure of the power amplifier more compact, thereby reducing the area occupied by the power amplifier and facilitating the miniaturization design of the RF front-end module.

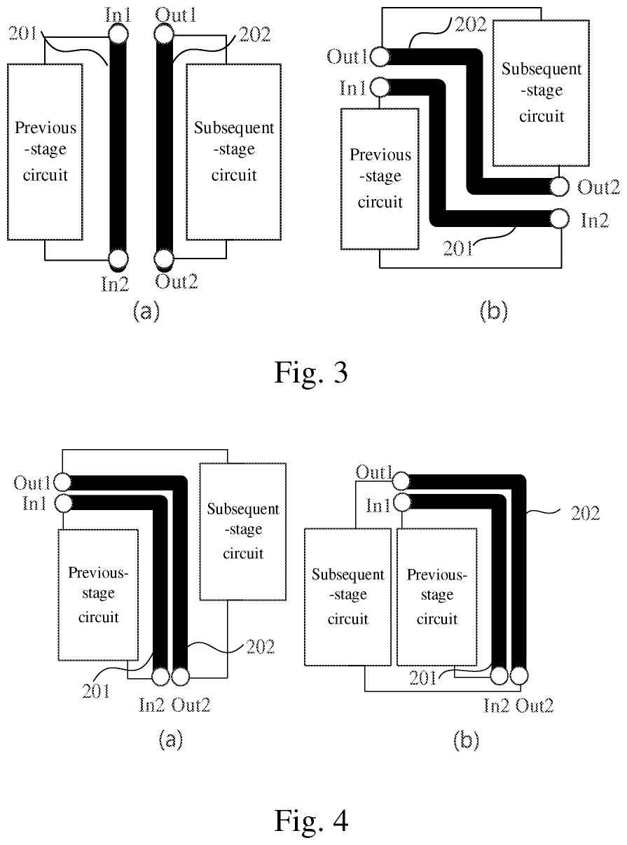

Exemplarily, as shown in (a) of FIG. 3, both the primary coupling line 201 and the secondary coupling line 202 are arranged in a straight-line shape. In this case, the transformer structure overall presents as a long strip structure with a narrow width, and there is no unusable closed space, resulting in a very small overall occupied area. At this time, the previous-stage and subsequent-stage circuits can be arranged on two sides of the transformer structure. The distance between the previous-stage circuit and the subsequent-stage circuit only needs to be slightly larger than the width of the transformer structure, making the overall layout of the power amplifier and the RF front-end module compact and neat.

Exemplarily, as shown in (b) of FIG. 3, both the primary coupling line 201 and the secondary coupling line 202 are arranged in a broken-line shape. The transformer structure overall presents as a ribbon structure with a narrow width and one or more bends. It can flexibly bend to accommodate the positional relationship between the previous-stage and subsequent-stage circuits, making the layout of the circuits and the transformer structure more compact. The bending manner of the primary coupling line 201 and the secondary coupling line 202 can be designed according to the layout requirements of the previous-stage and subsequent-stage circuits. For example, when a gap is required between the previous-stage and subsequent-stage circuits, the primary coupling line 201 and the secondary coupling line 202 can be interspersed between them as shown in (b) of FIG. 3 to make the overall layout more compact. When the previous-stage and subsequent-stage circuits need to be arranged close to each other, the primary coupling line 201 and the secondary coupling line 202 can adopt other bending manners, such as wrapping or half-wrapping around the previous-stage and/or subsequent-stage circuits. This allows the previous-stage and subsequent-stage circuits to be close to each other while utilizing the space on the inner side of the bends of the transformer structure, leading to a more compact layout and a smaller occupied area for the power amplifier and the RF front-end module.

Exemplarily, as shown in FIG. 4, both the primary coupling line 201 and the secondary coupling line 202 are arranged roughly in an L-shape, and the transformer structure overall presents as an L-shaped structure. The inner side of the bend of the L-shaped structure can be used to layout at least part of the circuit elements in the previous-stage and/or subsequent-stage circuits. That is, the transformer structure can be arranged half-wrapping around the previous-stage circuit, the subsequent-stage circuit, or both, to utilize the space at the bend of the L-shaped structure. This makes the layout of the power amplifier and the RF front-end module more compact and reduces the occupied area.

Optionally, when a relatively wide gap is required between the previous-stage circuit and the subsequent-stage circuit, one of the previous-stage circuit and the subsequent-stage circuit can be arranged on the inner side of the bend of the L-shaped structure, and the other can be arranged on the outer side of the bend of the L-shaped transformer structure, as shown in (a) of FIG. 4. When the previous-stage circuit and the subsequent-stage circuit need to be arranged close to each other, as shown in (b) of FIG. 4, both can be arranged on the inner side of the bend of the L-shaped transformer structure. This allows the previous-stage and subsequent-stage circuits to be close to each other while utilizing the space on the inner side of the L-shaped bend, thereby making the layout of the power amplifier and the RF front-end module more compact and reducing the occupied area.

Exemplarily, as shown in FIG. 5, both the primary coupling line 201 and the secondary coupling line 202 are arranged in a U-shape, and the transformer structure overall presents as a U-shaped structure. An inner side of the U-shaped structure can be used to layout at least part of the circuit elements in the previous-stage and/or subsequent-stage circuits to reasonably utilize the space on the inner side of the U-shaped structure, thereby making the layout of the power amplifier and the RF front-end module more compact and reducing the occupied area.

Optionally, when a relatively wide gap is required between the previous-stage circuit and the subsequent-stage circuit, one of the previous-stage circuit and the subsequent-stage circuit is arranged on the inner side of the U-shaped transformer structure, and the other is arranged on the outer side of the U-shaped structure. When the previous-stage circuit and the subsequent-stage circuit need to be arranged close to each other, as shown in (a) or (b) of FIG. 5, both can be arranged on the inner side of the U-shaped transformer structure. This allows the previous-stage and subsequent-stage circuits to be close to each other while utilizing the space on the inner side of the U-shaped structure, making the layout of the power amplifier and the RF front-end module more compact and the occupied area smaller.

As an implementation, in the examples of the straight-line shape, broken-line shape, L-shape, or U-shape, the length of the primary coupling line 201 is equal to the length of the secondary coupling line 202 to increase a coupling area between them and improve the coupling degree of the transformer structure. Specifically, for the transformer structure in the broken-line, L, or U shape, the length of the primary coupling line 201 and the length of the secondary coupling line 202 can be made equal by processing positions at the bends. Taking the L-shaped transformer structure as an example, its primary coupling line 201 and secondary coupling line 202 each include two line segments connected at a second angle. By switching the inner and outer positional relationship of the primary coupling line 201 and the secondary coupling line 202 at the bend, such that one line segment of the primary coupling line 201 is on the outer side of the secondary coupling line 202 while the other line segment is on the inner side, the lengths of the primary coupling line 201 and the secondary coupling line 202 can be equal or approximately equal. The U-shaped transformer structure or other broken-line transformer structures are similar; the length of the primary coupling line 201 can be made equal to that of the secondary coupling line 202 by switching their inner and outer positional relationships at at least one bend, and details are not repeated here.

It should be understood that, for broken-line, L-shaped, or U-shaped transformer structures, to avoid sudden changes in current direction on the primary and secondary coupling lines, the bends of these lines can be designed as circular arcs to buffer the change in current direction, reduce RF signal loss, and improve RF signal transmission efficiency.

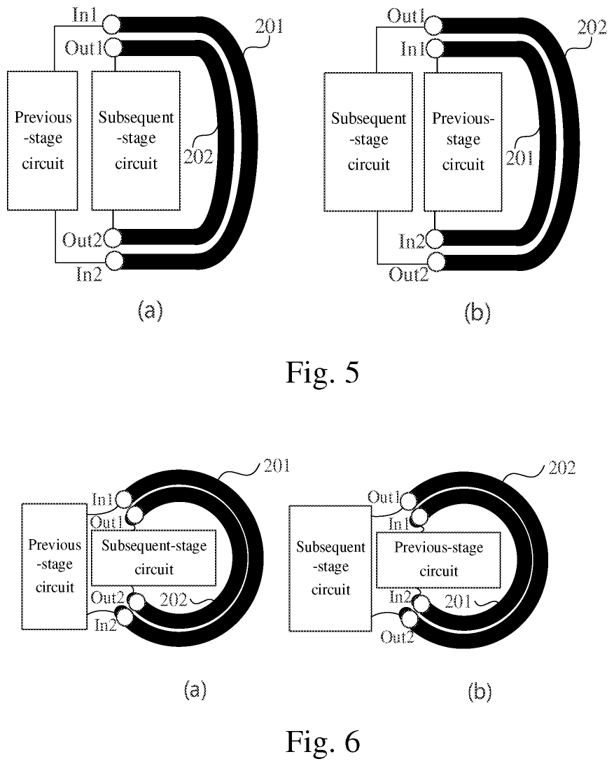

Exemplarily, as shown in FIG. 6, both the primary coupling line 201 and the secondary coupling line 202 are arranged in an arc-shape. Since the primary coupling line 201 and the secondary coupling line 202 follow each other and both are non-closed arcs, the resulting transformer structure also presents as a non-closed arc structure. This arc structure has openings at two ends, allowing at least part of the circuit elements in the previous-stage or subsequent-stage circuits to be arranged on the inner side of the arc structure. This effectively utilizes the space on the inner side of the arc, reduces area waste, and makes the layout of the power amplifier and the RF front-end module more compact with a smaller occupied area. Moreover, the current direction in the arc-shaped coupling lines changes relatively slowly, which can reduce RF signal loss and improve RF signal transmission efficiency.

Optionally, the central angles of the arcs formed by the primary coupling line 201 and the secondary coupling line 202 are both less than or equal to 270°, meaning the arcs are less than or equal to ¾ of a circle. This results in the arc of the transformer structure having an opening greater than or equal to ¼ of a circle, facilitating the layout of at least part of the circuit elements of the previous-stage or subsequent-stage circuits on the inner side of the arc structure.

Optionally, the central angles of the arcs formed by the primary coupling line 201 and the secondary coupling line 202 are both less than or equal to 180°, meaning the arcs are less than or equal to a semi-circle. This results in the arc of the transformer structure having an opening greater than or equal to a semi-circle, facilitating the layout of more circuit elements on the inner side of the arc structure.

Optionally, the central angles of the arcs formed by the primary coupling line 201 and the secondary coupling line 202 are both greater than or equal to 90°, meaning the arcs are greater than or equal to ¼ of a circle. This ensures that the primary coupling line 201 and the secondary coupling line 202 have a certain routing length to satisfy the inductance required for impedance matching.

As an implementation, when the primary coupling line 201 and the secondary coupling line 202 adopt the arc structure, the radius and central angle of the arc structure can be determined based on the circuit area of the previous-stage or subsequent-stage circuit, as well as the inductance required for impedance matching. The radius of the arc structure can be positively correlated with the inductance required for impedance matching and the circuit area to be arranged on the inner side of the arc structure. Thus, at the same central angle, a larger radius results in a larger space on the inner side of the arc structure, allowing for the layout of more circuit elements and providing longer routing for greater inductance. Furthermore, the central angle of the arc structure can be negatively correlated with the circuit area to be arranged on the inner side of the arc structure. That is, the larger the circuit area to be arranged on the inner side, the smaller the central angle of the arc structure and the larger the corresponding opening, which facilitates the layout of circuit elements.

In each of the above examples, the previous-stage circuit refers to a circuit connected to the primary coupling line 201, and an output signal of the previous-stage circuit is an input signal of the transformer structure. The subsequent-stage circuit refers to a circuit connected to the secondary coupling line 202, and a signal output by the secondary coupling line 202 is an input signal of the subsequent-stage circuit.

Exemplarily, when the transformer structure serves as an input impedance matching circuit in a power amplifier, its subsequent-stage circuit can include a power amplification circuit. For example, the primary coupling line 201 of the transformer structure can be used to receive an RF signal to be amplified, and the secondary coupling line 202 can be used to connect to an input terminal of the power amplification circuit. After the RF signal to be amplified undergoes input impedance matching via the transformer structure, it is then power-amplified by the power amplification circuit.

Exemplarily, when the transformer structure serves as an inter-stage impedance matching circuit in a multi-stage power amplifier, its previous-stage and subsequent-stage circuits can respectively be power amplification circuits of different stages in the multi-stage power amplifier. Taking a two-stage power amplifier as an example, the primary coupling line 201 of the transformer structure can be used to connect to an output terminal of a first-stage power amplifier to receive an RF signal output by a first-stage power amplification circuit. The secondary coupling line 202 can be used to connect to an input terminal of a second-stage power amplification circuit to input the inter-stage impedance-matched RF signal into the second-stage power amplification circuit for second-stage power amplification.

Exemplarily, when the transformer structure serves as an output impedance matching circuit in a power amplifier, its previous-stage circuit can include a power amplification circuit. The primary coupling line 201 of the transformer structure can be used to receive an RF signal from the power amplification circuit, and the secondary coupling line 202 outputs the coupled RF signal that has undergone output impedance matching to other modules in the RF front-end module, such as an RF switch module.

It should be understood that in some RF front-end modules, multiple impedance matching circuits are provided simultaneously, and the transformer structure can be applied to one or more impedance matching circuits in the RF front-end module. When multiple impedance matching circuits all adopt the aforementioned transformer structure, the power amplification circuit is the previous-stage circuit for some transformer structures, while the power amplification circuit is the subsequent-stage circuit for others.

In the embodiments of this application, the transformer structure can be integrated in a chip or disposed on a substrate, which can be set according to application requirements. For example, a substrate provides more routing space than a chip, thereby achieving larger inductance. Therefore, when the primary coupling line and the secondary coupling line of the transformer require larger inductance, the transformer structure can be disposed on the substrate. When the inductance requirement for the primary and secondary coupling lines is smaller, the transformer structure can be disposed in a chip, specifically in the chip where the power amplifier is located. As another example, when the transformer structure serves as an inter-stage impedance matching circuit of the power amplifier, the transformer structure needs to be respectively connected to multiple stages of power amplification circuits of the power amplifier and has a low inductance requirement for the primary and secondary coupling lines. In this case, the transformer structure can be integrated in the chip where the power amplifier is located to facilitate circuit connection.

In the embodiments of this application, since the primary coupling line and the secondary coupling line follow each other, the length of each coupling line is roughly the same, and one primary coupling line and one secondary coupling line can achieve an inductance ratio of approximately 1:1. In some application scenarios, if an inductance ratio other than 1:1 is required, the number of primary coupling lines 201 and/or secondary coupling lines 202 can be multiple. An inductance ratio other than 1:1 is achieved through a series connection between multiple primary coupling lines and/or a series connection between multiple secondary coupling lines 202. For example, when a 2:1 inductance ratio is required, two primary coupling lines and one secondary coupling line can be provided, with the two primary coupling lines connected in series to have approximately twice the inductance of the secondary coupling line, thereby achieving a 2:1 inductance ratio. In this case, to improve the coupling degree between the primary and secondary coupling lines, the secondary coupling line can be arranged between the two primary coupling lines so that the secondary coupling line can couple with both primary coupling lines, thereby enhancing the coupling degree of the transformer structure. Similarly, when a 1:2 inductance ratio is required, one primary coupling line and two secondary coupling lines can be provided, with the two secondary coupling lines connected in series to have approximately twice the inductance of the primary coupling line, thereby achieving a 1:2 inductance ratio. In this case, to improve the coupling degree between the primary and secondary coupling lines, the primary coupling line can be arranged between the two secondary coupling lines so that both secondary coupling lines can couple well with the primary coupling line.

In at least one embodiment, to improve a coupling degree between a primary coupling line and a secondary coupling line, at least one primary coupling line can be split into two parallel coupling lines, and a secondary coupling line is arranged between the two split primary coupling lines to strengthen a coupling degree between the primary and secondary coupling lines. Exemplarily, a line width of each primary coupling line can be slightly smaller than or remain roughly the same as a line width of the secondary coupling line to achieve a better coupling degree of the transformer structure. Alternatively, at least one secondary coupling line can be split into two parallel coupling lines, and a primary coupling line is arranged between the two split secondary coupling lines to strengthen the coupling degree between them. Optionally, a line width of each split secondary coupling line can be slightly smaller than or remain roughly the same as the line width of the primary coupling line, further enhancing the coupling degree of the transformer structure.

In at least one embodiment, the primary coupling line or the secondary coupling line can further be split into more lines, and the primary coupling lines and the secondary coupling lines are interleaved to further increase a coupling area and enhance the coupling degree of the transformer structure.

Optionally, when both the number of primary coupling lines and the number of secondary coupling lines are multiple and the lines are located in a same plane, coupling lines on two sides can be of the same type to ensure balance of the transformer structure. For example, if both sides are primary coupling lines or both sides are secondary coupling lines, a difference between the number of primary coupling lines and the number of secondary coupling lines needs to be 1. Exemplarily, the transformer structure can include N primary coupling lines and M secondary coupling lines, and the N primary coupling lines and the M secondary coupling lines are interleaved; both N and M are positive integers, and N=M+1 or N=M−1. For instance, when there is one more primary coupling line than secondary coupling lines (N=M+1), the primary and secondary coupling lines are interleaved in an order of primary→secondary . . . →primary. When there is one more secondary coupling line than primary coupling lines (N=M−1), the primary and secondary coupling lines are interleaved in an order of secondary→primary . . . →secondary. In this way, the balance of the transformer structure is ensured while enhancing its coupling degree.

According to the above embodiments, the number of primary coupling lines 201 and the number of secondary coupling lines 202 can each be one or more. When there are multiple primary coupling lines 201, they can be connected in series or in parallel. When there are multiple secondary coupling lines 202, they can be connected in series or in parallel. The number of primary coupling lines 201, the number of secondary coupling lines 202, the connection relationship among multiple primary coupling lines 201, and the connection relationship among multiple secondary coupling lines 202 can be set according to a required inductance ratio and coupling degree.

In some embodiments, when each of the primary coupling line and the secondary coupling line is provided as a single line, the primary coupling line and the secondary coupling line are located in a same plane. When there are multiple primary coupling lines or secondary coupling lines, at least one primary coupling line and at least one secondary coupling line are located in a same plane. Arranging at least one primary coupling line and at least one secondary coupling line in the same plane allows them to be fabricated in a same metal layer of a chip or a substrate, thereby reducing the number of metal layers occupied by the balun and decreasing costs. Moreover, fabrication in the same metal layer can make a thickness of the primary coupling line the same as a thickness of the secondary coupling line, resulting in a better coupling degree of the balun.

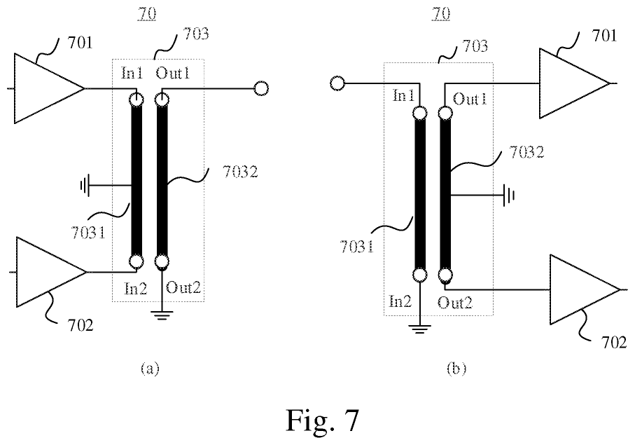

The embodiments of this application further provide a power amplifier. As shown in FIG. 7, a power amplifier 70 can include a first power amplification circuit 701, a second power amplification circuit 702, and a balun 703. The first power amplification circuit 701 and the second power amplification circuit 702 are respectively connected to the balun 703. The balun 703 includes a primary coupling line 7031 and a secondary coupling line 7032. The primary coupling line 7031 includes a first input terminal In1 and a second input terminal In2; the secondary coupling line 7032 includes a first output terminal Out1 and a second output terminal Out2.

In the embodiments of this application, the power amplifier 70 includes at least one stage of a differential power amplification circuit. For example, the first power amplification circuit 701 and the second power amplification circuit 702 can constitute a one-stage differential power amplification circuit. Optionally, the power amplifier 70 can be a push-pull power amplifier, a balanced power amplifier, or a combination of at least one stage of a single-ended power amplification circuit and at least one stage of a differential power amplification circuit.

Optionally, the balun 703 is used to achieve input impedance matching or output impedance matching of the differential power amplification circuit. When the power amplifier is a multi-stage power amplifier, the balun can also be used to achieve inter-stage impedance matching of the multi-stage power amplifier.

As an implementation, the balun 703 can be used for output impedance matching of the differential power amplification circuit and to achieve balanced-to-unbalanced conversion of RF signals. That is, balanced RF signals amplified and output by the first power amplification circuit 701 and the second power amplification circuit 702 are converted into an unbalanced RF signal for output. For example, the signal is output to a switch circuit at a back end of the power amplifier, and the switch circuit selectively outputs the unbalanced RF signal to an antenna port.

As another implementation, the balun 703 can be used for input impedance matching or inter-stage impedance matching of the differential power amplification circuit. When an input RF signal of the differential power amplification circuit is an unbalanced signal, or when a single-ended power amplification circuit is further provided at front ends of the first power amplification circuit 701 and the second power amplification circuit 702, the balun 703 is further used to achieve unbalanced-to-balanced conversion of the RF signals. That is, an unbalanced RF input signal is converted into balanced RF signals, and the first power amplification circuit 701 and the second power amplification circuit 702 perform power amplification on the balanced RF signals.

In the embodiments of this application, the routing path of the primary coupling line 7031 from the first input terminal In1 to the second input terminal In2 is referred to as a first routing path, and the routing path of the secondary coupling line 7032 from the first output terminal Out1 to the second output terminal Out2 is referred to as a second routing path. The first routing path follows the second routing path. In other words, if the first input terminal In1 is taken as a starting point of the primary coupling line 7031, the second input terminal In2 as an ending point, the first output terminal Out1 as a starting point of the secondary coupling line 7032, and the second output terminal Out2 as an ending point, then the primary coupling line 7031 and the secondary coupling line 7032 each have roughly the same direction and exhibit roughly the same shape from the starting point to the ending point.

Since the paths of the primary coupling line 7031 and the secondary coupling line 7032 from the starting point to the ending point follow each other, every segment of the primary coupling line can couple with a corresponding segment of the secondary coupling line. Conversely, every segment of the secondary coupling line can also couple with a corresponding segment of the primary coupling line, providing a better coupling degree compared to the structure shown in FIG. 1.

On the other hand, because the primary coupling line 7031 and the secondary coupling line 7032 are coupled to each other, the distance between them is very small, and they follow each other. Therefore, the starting points of the primary coupling line 7031 and the secondary coupling line 7032 are close to each other, and the ending points are also close to each other. In other words, the first input terminal In1 of the primary coupling line 7031 and the first output terminal Out1 of the secondary coupling line 7032 are arranged close to each other, and the second input terminal In2 of the primary coupling line 7031 and the second output terminal Out2 of the secondary coupling line 7032 are arranged close to each other.

Based on this, the primary coupling line 7031 and the secondary coupling line 7032 of the transformer structure overall present a line-shaped structure. Their shapes and arrangement positions can be flexibly set to adapt to the layout of other circuits in the power amplifier. This makes the overall structure of the power amplifier more compact, thereby reducing the area occupied by the power amplifier and facilitating the miniaturization design of the RF front-end module.

In some embodiments, the balun 703 can adopt the same structure as the transformer structure 20 of any of the preceding embodiments. For example, the primary coupling line and the secondary coupling line can be arranged in a straight-line shape, a broken-line shape, an arc-shape, a U-shape, an L-shape, etc. For specific details, reference can be made to the descriptions of the preceding embodiments, and details are not repeated here.

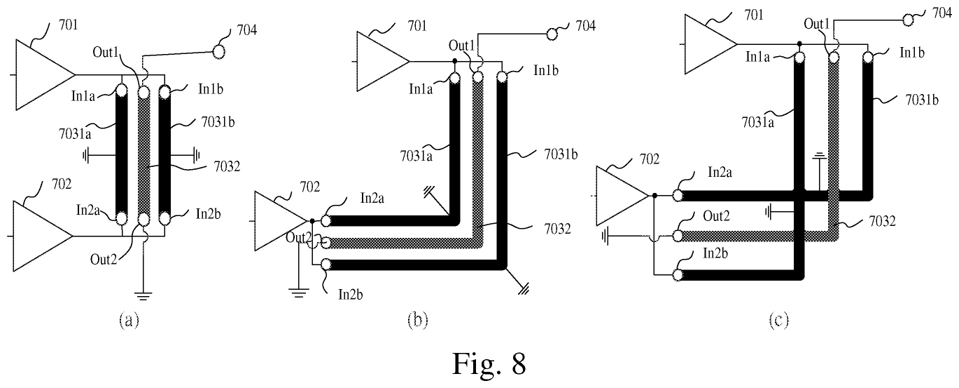

In some embodiments, as shown in FIG. 8, the primary coupling line 7031 includes a first primary coupling line 7031a and a second primary coupling line 7031b. The first primary coupling line 7031a and the second primary coupling line 7031b respectively have first input terminals In1a, In1b and second input terminals In2a, In2b. Both the routing path of the first primary coupling line 7031a from the first input terminal In1a to the second input terminal In2a and the routing path of the second primary coupling line 7031b from the first input terminal In1b to the second input terminal In2b are referred to as a first routing path. Then the first routing paths of both the first primary coupling line 7031a and the second primary coupling line 7031b follow the second routing path of the secondary coupling line 7032. In the embodiments of this application, the secondary coupling line 7032 is arranged between the first primary coupling line 7031a and the second primary coupling line 7031b to facilitate a high coupling degree with both the first primary coupling line 7031a and the second primary coupling line 7031b, thereby improving the coupling coefficient of the balun 703.

Optionally, the first primary coupling line 7031a and the second primary coupling line 7031b can be connected in series or in parallel. The inductance of a coupling line is mainly related to its line length. When two coupling lines are connected in series, it is equivalent to increasing the line length of the coupling line, and the inductance increases accordingly. When two coupling lines of the same length are connected in parallel, it is equivalent to increasing the line width of the coupling line while the line length remains unchanged, which has a smaller effect on the inductance. Therefore, in some implementations, the inductance ratio between the primary and secondary sides can be adjusted by increasing the number of primary/secondary coupling lines and connecting multiple primary/secondary coupling lines in series.

As an implementation, the balun 703 is used for output impedance matching of the power amplifier. When the first primary coupling line 7031a and the second primary coupling line 7031b are connected in parallel, the input end of the balun 703 is connected to the output terminals of the first power amplification circuit 701 and the second power amplification circuit 702. Specifically, as shown in FIG. 8, the first input terminal In1a of the first primary coupling line 7031a and the first input terminal In1b of the second primary coupling line 7031b are respectively connected to the output terminal of the first power amplification circuit 701. The second input terminal In2a of the first primary coupling line 7031a and the second input terminal In2b of the second primary coupling line 7031b are respectively connected to the output terminal of the second power amplification circuit 702. The first output terminal Out1 of the secondary coupling line 7032 is used to connect to a signal transmission terminal 704, and the second output terminal Out2 of the secondary coupling line 7032 is used to be grounded.

In this implementation, the balun 703 is a balanced-to-unbalanced balun that can transform balanced (differential) signals received at the input end into an unbalanced (single-ended) signal for reception by a subsequent-stage single-ended circuit (such as an RF switch). Exemplarily, the first output terminal Out1 of the balun 703 can be connected to an RF switch in the RF front-end module. When the RF switch is turned on, the amplified RF signal is transmitted to an antenna port connected to the RF switch and is then emitted through an antenna connected to the antenna port. At this time, the balun 703 serves as an output balun of the power amplifier, connected between the power amplifier and a subsequent-stage circuit. It can match the output impedance of the power amplifier with the input impedance of the subsequent-stage circuit, thereby reducing the loss of RF signals during transmission.

This implementation improves the coupling degree of the balun by splitting the primary coupling line 7031 into two parallel coupling lines 7031a and 7031b, allowing the secondary coupling line 7032 to be sandwiched between the two primary coupling lines 7031a and 7031b.

Since the two primary coupling lines 7031a and 7031b are in a parallel relationship, the effect on inductance is small. When the line lengths of the two primary coupling lines 7031a, 7031b and the secondary coupling line 7032 are the same, the inductance ratio between the primary and secondary sides of the balun structure is approximately 1:1. Optionally, the widths of the first primary coupling line and the second primary coupling line can be slightly smaller than or remain roughly the same as the line width of the secondary coupling line to achieve a better coupling degree of the balun 703.

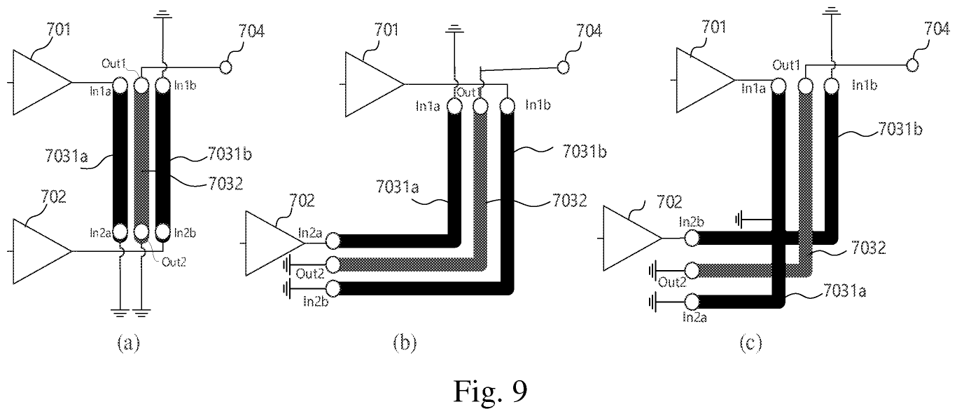

As an implementation, the balun 703 is used for output impedance matching of the power amplifier. When the first primary coupling line 7031a and the second primary coupling line 7031b are connected in series, the input end of the balun 703 is connected to the output terminals of the first power amplification circuit 701 and the second power amplification circuit 702. Specifically, as shown in FIG. 9, the first input terminal In1a of the first primary coupling line 7031a is configured to be connected to the output terminal of the first power amplification circuit 701, and the second input terminal In2a of the first primary coupling line 7031a is configured to be grounded. The first input terminal In1b of the second primary coupling line 7031b is configured to be grounded, and the second input terminal In2b of the second primary coupling line 7031b is configured to be connected to the output terminal of the second power amplification circuit 702. The first output terminal Out1 of the secondary coupling line 7032 is configured to be connected to a signal transmission terminal, and the second output terminal Out2 of the secondary coupling line 7032 is configured to be grounded.

In this implementation, since both the second input terminal In2a of the first primary coupling line 7031a and the first input terminal In1b of the second primary coupling line 7031b are grounded, the first primary coupling line 7031a and the second primary coupling line 7031b are equivalent to being connected in series between the output terminal of the first power amplification circuit 701 and the output terminal of the second power amplification circuit 702. Thus, they receive balanced signals output by the differential power amplification circuit including the first power amplification circuit 701 and the second power amplification circuit 702. One end of the secondary coupling line 7032 is grounded and the other end serves as an output, thereby converting the balanced signals received by the primary side into an unbalanced signal for output. Similar to the preceding embodiments, the balun 703 can also be used to achieve impedance matching between a previous-stage circuit and a subsequent-stage circuit to reduce signal loss during transmission.

The lengths of the first primary coupling line 7031a, the second primary coupling line 7031b, and the secondary coupling line 7032 are the same to improve the coupling coefficient of the balun. At this time, since the first primary coupling line 7031a and the second primary coupling line 7031b are connected in series, the line length of the primary coupling line is equivalent to being doubled, which is twice the line length of the secondary coupling line. Therefore, the balun 703 can achieve a 2:1 inductance ratio.

This implementation improves the coupling degree of the balun by splitting the primary coupling line 7031 into two coupling lines 7031a and 7031b, allowing the secondary coupling line 7032 to be sandwiched between the two primary coupling lines 7031a and 7031b. By connecting the two coupling lines 7031a and 7031b in series, the inductance of the primary coupling line can further be increased without increasing the length of a single coupling line. This achieves adjustment of the inductance ratio of the balun and satisfies requirements of application scenarios with high inductance demand using a smaller area.

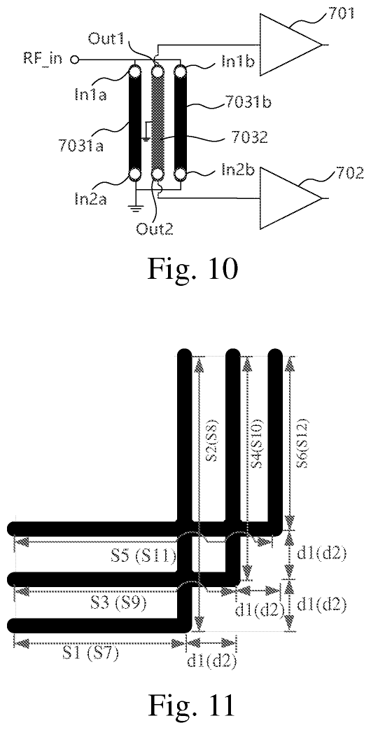

As an implementation, the balun 703 is used for input impedance or inter-stage impedance matching of the power amplifier. When the first primary coupling line 7031a and the second primary coupling line 7031b are connected in parallel, the output end of the balun 703 is connected to the input terminals of the first power amplification circuit 701 and the second power amplification circuit 702. Specifically, as shown in FIG. 10, the first input terminal In1a of the first primary coupling line 7031a and the first input terminal In1b of the second primary coupling line 7031b are respectively configured to receive an RF input signal RF-in. The second input terminal In2a of the first primary coupling line 7031a and the second input terminal In2b of the second primary coupling line 7031b are respectively configured to be grounded. The first output terminal Out1 of the secondary coupling line 7032 is connected to the input terminal of the first power amplification circuit 701, and the second output terminal Out2 of the secondary coupling line 7032 is connected to the input terminal of the second power amplification circuit 702.

In this implementation, the balun 703 is an unbalanced-to-balanced balun that can transform an unbalanced RF input signal RF-in, received from a power amplifier input terminal or a single-ended power amplification circuit output terminal of a previous stage, into balanced RF signals to facilitate reception and processing by a differential power amplification circuit of a subsequent stage. When the balun 703 serves as an input balun of the power amplifier, it is connected between a previous-stage circuit and the input terminals of the differential power amplification circuit, enabling conversion of a single-ended signal output from the previous stage into differential signals and matching the output impedance of the previous-stage circuit with the input impedance of the differential power amplification circuit, thereby reducing the loss of RF signals during transmission. When the balun 703 is an inter-stage matching balun of the power amplifier, the power amplifier includes at least one stage of a single-ended amplification circuit and at least one stage of a differential amplification circuit, with the single-ended amplification circuit being at a previous stage of the differential amplification circuit. The balun 703 is connected between adjacent stages of the single-ended amplification circuit and the differential amplification circuit to convert a single-ended RF signal output from the previous-stage single-ended amplification circuit into differential RF signals and match the output impedance of the previous-stage single-ended amplification circuit with the input impedance of the subsequent-stage differential amplification circuit, thereby reducing the loss of RF signals during transmission from the previous-stage amplification circuit to the subsequent-stage amplification circuit.

This implementation improves the coupling degree of the balun by splitting the primary coupling line 7031 into two parallel coupling lines 7031a and 7031b, allowing the secondary coupling line 7032 to be sandwiched between the two primary coupling lines 7031a and 7031b, thereby enhancing the coupling degree of the balun with almost no impact on the inductance ratio of the balun.

Optionally, the first primary coupling line 7031a, the second primary coupling line 7031b, and the secondary coupling line 7032 can be arranged in a straight-line shape, a broken-line shape, an arc-shape, a U-shape, an L-shape, or other shapes as required to adapt to the layout of the first power amplification circuit 701, the second power amplification circuit 702, and other circuits.

In some implementations, when the balun 703 has at least one bending segment, if the extension directions of a first segment and a last segment of the balun 703 are different, the first primary coupling line, the second primary coupling line, and the secondary coupling line can cross each other at the at least one bending segment so that the overall lengths of the first primary coupling line, the second primary coupling line, and the secondary coupling line are roughly equal, thereby improving the coupling degree of the balun 703. The extension direction of the first segment of the balun refers to a direction extending from the first input ports In1a,In1b and the first output port Out1 along each coupling line; the extension direction of the last segment refers to a direction extending toward the second input ports In2a, In2b and the second output port Out2 along each coupling line.

Specifically, the crossing manner of the first primary coupling line, the second primary coupling line, and the secondary coupling line can be an exchange of inner and outer relationships between the innermost coupling line and the outermost coupling line. For example, if in a first section of the bend, the first primary coupling line is on the outer side of the secondary coupling line and the second primary coupling line is on the inner side of the secondary coupling line, then in a second section of the bend, the inner and outer relationship of the first primary coupling line and the second primary coupling line is swapped, adjusting such that the first primary coupling line is on the inner side of the secondary coupling line and the second primary coupling line is on the outer side of the secondary coupling line.

Exemplarily, when a broken-line shape (including an L-shape) structure is adopted, the balun 703 includes at least one bending segment. At the bending segment, the first primary coupling line 7031a includes a first line segment and a second line segment connected at a first angle, the secondary coupling line 7032 includes a third line segment and a fourth line segment connected at the first angle, and the second primary coupling line 7031b includes a fifth line segment and a sixth line segment connected at the first angle. When the number of bending segments of the balun 703 is odd, at all or some of the odd number of bending segments, the first line segment, the third line segment, and the fifth line segment are parallel to each other and have lengths that sequentially increase. The second line segment, the fourth line segment, and the sixth line segment are parallel to each other and have lengths that sequentially decrease. In this way, the sum of the first line segment and the second line segment, the sum of the third line segment and the fourth line segment, and the sum of the fifth line segment and the sixth line segment can be equal or roughly equal. This results in the lengths of the first primary coupling line 7031a, the second primary coupling line 7031b, and the secondary coupling line 7032 being equal or roughly equal, thereby increasing the coupling area of these lines and improving the coupling degree of the balun.

Exemplarily, as shown in FIG. 11, the lengths of the first line segment, the second line segment, the third line segment, the fourth line segment, the fifth line segment, and the sixth line segment are respectively denoted as S1, S2, S3, S4, S5, and S6. A length difference between the third line segment and the first line segment (S3−S1), a length difference between the fifth line segment and the third line segment (S5−S3), a length difference between the second line segment and the fourth line segment (S2−S4), and a length difference between the fourth line segment and the sixth line segment (S4−S6) are equal and are all a first value d1. That is, S3−S1=S5−S3=S2−S4=S4−S6=d1. Then S1+S2=S3+S4=S5+S6. Thus, the lengths of the first primary coupling line 7031a, the second primary coupling line 7031b, and the secondary coupling line 7032 are equal, maximizing the coupling degree of the balun.

Optionally, the first angle is greater than or equal to 90°, preventing sharp changes in the direction of current flowing through each coupling line at the bend, thereby reducing RF signal loss and improving RF signal transmission efficiency. When the first angle is 90°, making a gap between the third line segment and the first and fifth line segments equal to a gap between the fourth line segment and the second and sixth line segments results in equal lengths for the first primary coupling line 7031a, the second primary coupling line 7031b, and the secondary coupling line 7032. This maximizes the coupling degree and impedance matching effect of the balun.

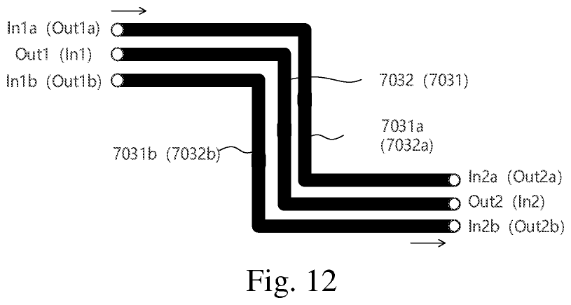

In some implementations, as shown in FIG. 12, when the balun 703 has at least two bending segments, if a first segment and a last segment of the balun 703 have the same extension direction, the first primary coupling line, the second primary coupling line, and the secondary coupling line can remain parallel without crossing at each bending segment of the balun 703. In this case, the lengths of each coupling line in the balun 703 are still equal or roughly equal, and the balun 703 still maintains a high coupling degree.

In some embodiments, the secondary coupling line 7032 of the balun 703 includes a first secondary coupling line 7032a and a second secondary coupling line 7032b, each having a first output terminal and a second output terminal. Both a routing path of the first secondary coupling line 7032a from the first output terminal to the second output terminal and a routing path of the second secondary coupling line 7032b from the first output terminal to the second output terminal are referred to as a second routing path. Then the first routing path of the primary coupling line 7031 and the second routing paths of the first secondary coupling line 7032a and the second secondary coupling line 7032b follow each other.

In the embodiments of this application, the primary coupling line 7031 is arranged between the first secondary coupling line 7032a and the second secondary coupling line 7032b so that both secondary coupling lines can couple with the primary coupling line 7031, thereby improving the coupling degree of the balun 703.

Optionally, the first secondary coupling line 7032a and the second secondary coupling line 7032b can be connected in series or in parallel.

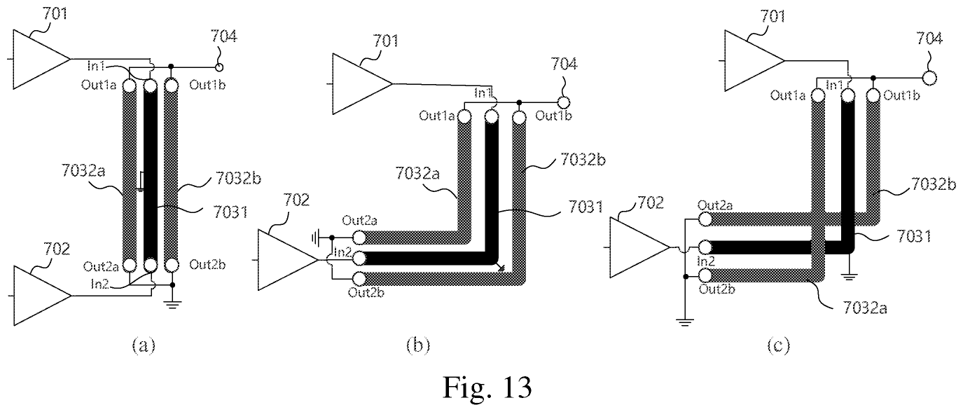

As an implementation, the balun 703 serves as an output balun of the power amplifier for output impedance matching, and the first secondary coupling line 7032a and the second secondary coupling line 7032b can be connected in parallel. As shown in FIG. 13, the first input terminal In1 of the primary coupling line 7031 is connected to the output terminal of the first power amplification circuit 701, and the second input terminal In2 of the primary coupling line 7031 is connected to the output terminal of the second power amplification circuit 702. The first output terminal Out1a of the first secondary coupling line 7032a and the first output terminal Out1b of the second secondary coupling line 7032b are both configured to connect to the signal transmission terminal 704. The second output terminal Out2a of the first secondary coupling line 7032a and the second output terminal Out2b of the second secondary coupling line 7032b are both configured to be grounded. The balun 703 of this implementation is a balanced-to-unbalanced balun that can transform input differential RF signals into an unbalanced RF signal for output and achieve impedance matching between the output ends of the power amplifier (i.e., the output terminals of the first and second power amplification circuits 701 and 702) and an input end of a subsequent-stage circuit.

To maximize the coupling degree between the primary and secondary coupling lines, the lengths of the first secondary coupling line 7032a, the second secondary coupling line 7032b, and the primary coupling line 7031 can be the same. Since the first secondary coupling line 7032a and the second secondary coupling line 7032b are in a parallel relationship, the effect on inductance is small, and the inductance ratio between the primary and secondary sides of the balun 703 is approximately 1:1.

Optionally, the widths of the first secondary coupling line 7032a and the second secondary coupling line 7032b can be set to be slightly smaller than or remain roughly the same as the line width of the primary coupling line 7031 to achieve a better coupling degree of the balun 703.

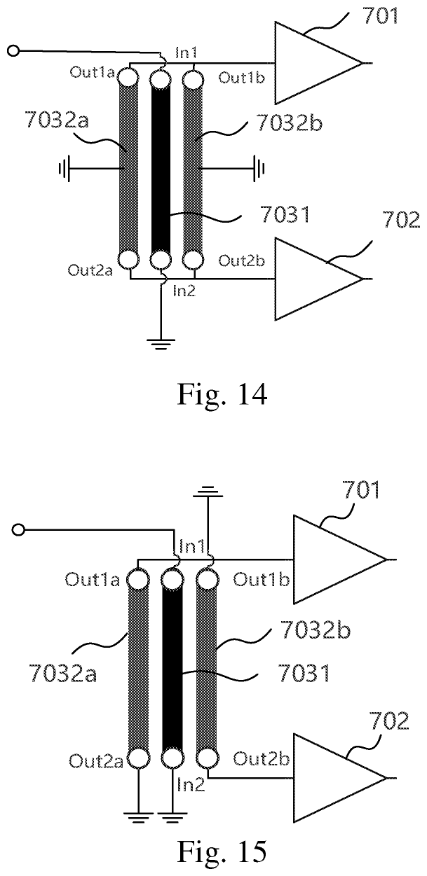

As an implementation, the balun 703 is used for input impedance matching or inter-stage impedance matching of the power amplifier. When the first secondary coupling line 7032a and the second secondary coupling line 7032b are connected in parallel, as shown in FIG. 14, the first input terminal In1 of the primary coupling line 7031 is used to receive the input RF signal RF_in, and the second input terminal In2 of the primary coupling line 7031 is used to be grounded. The first output terminal Out1a of the first secondary coupling line 7032a and the first output terminal Out1b of the second secondary coupling line 7032b are both connected to the input terminal of the first power amplification circuit 701. The second output terminal Out2a of the first secondary coupling line 7032a and the second output terminal Out2b of the second secondary coupling line 7032b are both connected to the input terminal of the second power amplification circuit 702.

In this implementation, the balun 703 is an unbalanced-to-balanced balun that can transform an input single-ended RF signal into differential RF signals and output the differential RF signals to a differential power amplification circuit including the first and second power amplification circuits for power amplification. The balun 703 can also achieve impedance matching between the output end of a previous-stage circuit and the input ends of the differential power amplification circuit (i.e., the input terminals of the first and second power amplification circuits 701 and 702).

To maximize the coupling degree between the primary and secondary coupling lines, the lengths of the first secondary coupling line 7032a, the second secondary coupling line 7032b, and the primary coupling line 7031 can be the same. At this time, the inductance ratio between the primary and secondary sides of the balun 703 is approximately 1:1.

Optionally, the widths of the first secondary coupling line 7032a and the second secondary coupling line 7032b can be set to be slightly smaller than or remain roughly the same as the line width of the primary coupling line 7031, which can further enhance the coupling degree of the balun 703.

As an implementation, the balun 703 is used for input impedance matching or inter-stage impedance matching of the power amplifier. When the first secondary coupling line 7032a and the second secondary coupling line 7032b are connected in series, as shown in FIG. 15, the first input terminal In1 of the primary coupling line 7031 is used to receive the input RF signal RF_in, and the second input terminal In2 of the primary coupling line 7031 is used to be grounded. The first output terminal Out1a of the first secondary coupling line 7032a is connected to the input terminal of the first power amplification circuit 701, and the first output terminal Out1b of the second secondary coupling line 7032b is connected to the input terminal of the second power amplification circuit 702. In this implementation, the balun 703 is an unbalanced-to-balanced balun. Its function can refer to the preceding embodiments and is not repeated here.

Similarly, to maximize the coupling degree between the primary and secondary coupling lines, the lengths of the first secondary coupling line 7032a, the second secondary coupling line 7032b, and the primary coupling line 7031 can be the same. Since connecting two secondary coupling lines in series is equivalent to increasing the line length of the secondary side, the inductance of the secondary coupling line is roughly doubled, thereby achieving an inductance ratio of approximately 1:2.

Optionally, in each of the above implementations, the first secondary coupling line 7032a, the second secondary coupling line 7032b, and the primary coupling line 7031 can be arranged in a straight-line shape, a broken-line shape, an arc-shape, a U-shape, an L-shape, or other shapes as required to adapt to the layout of the first power amplification circuit 701, the second power amplification circuit 702, and other circuits.

In some implementations, when the balun 703 has at least one bending segment, if the extension directions of the first segment and the last segment of the balun 703 are different, the first secondary coupling line 7032a, the second secondary coupling line 7032b, and the primary coupling line 7031 can cross each other at the at least one bending segment. This makes the overall lengths of the first secondary coupling line 7032a, the second secondary coupling line 7032b, and the primary coupling line 7031 roughly equal, thereby improving the coupling degree of the balun 703. The extension direction of the first segment of the balun refers to a direction extending from the first input port In1 and the first output ports Out1a, Out1b along each coupling line; the extension direction of the last segment refers to a direction extending toward the second input port In2 and the second output ports Out2a, Out2b along each coupling line.

Specifically, the crossing manner of the first secondary coupling line 7032a, the second secondary coupling line 7032b, and the primary coupling line 7031 can be an exchange of inner and outer relationships between the innermost coupling line and the outermost coupling line. For example, if in a first section of the bend, the first secondary coupling line is on the outer side of the primary coupling line and the second secondary coupling line is on the inner side of the primary coupling line, then in a second section of the bend, the inner and outer relationship of the first secondary coupling line and the second secondary coupling line is swapped, adjusting such that the first secondary coupling line is on the inner side of the primary coupling line and the second secondary coupling line is on the outer side of the primary coupling line.

Exemplarily, when a broken-line shape (including an L-shape) structure is adopted, the balun 703 includes at least one bending segment. At the bending segment, the first secondary coupling line 7032a includes a seventh line segment and an eighth line segment connected at a second angle, the primary coupling line 7031 includes a ninth line segment and a tenth line segment connected at the second angle, and the second secondary coupling line 7032b includes an eleventh line segment and a twelfth line segment connected at the second angle. When the number of bending segments of the balun 703 is odd, at all or some of the odd number of bending segments, the seventh line segment, the ninth line segment, and the eleventh line segment are parallel to each other and have lengths that sequentially increase. The eighth line segment, the tenth line segment, and the twelfth line segment are parallel to each other and have lengths that sequentially decrease. In this way, the sum of the seventh and eighth line segments, the sum of the ninth and tenth line segments, and the sum of the eleventh and twelfth line segments can be equal or roughly equal. This results in the lengths of the first secondary coupling line 7032a, the second secondary coupling line 7032b, and the primary coupling line 7031 being equal or roughly equal, thereby increasing the coupling area and improving the coupling degree of the balun.

Exemplarily, as shown in FIG. 11, the lengths of the seventh to twelfth line segments are respectively denoted as S7, S8, S9, S10, S11, and S12. A length difference between the ninth line segment and the seventh line segment (S9−S7), a length difference between the eleventh line segment and the ninth line segment (S11−S9), a length difference between the eighth line segment and the tenth line segment (S8−S10), and a length difference between the tenth line segment and the twelfth line segment (S10−S12) are equal and are all a second value d2. That is, S9−S7=S11−S9=S8−S10=S10−S12=d2. Then S7+S8=S9+S10=S11+S12. Thus, the lengths of the first secondary coupling line 7032a, the second secondary coupling line 7032b, and the primary coupling line 7031 are equal, maximizing the coupling degree of the balun.

Optionally, the second angle is greater than or equal to 90°, preventing sharp changes in the direction of current flowing through each coupling line at the bend, thereby reducing RF signal loss and improving RF signal transmission efficiency. When the second angle is 90°, making a gap between the ninth line segment and the seventh and eleventh line segments equal to a gap between the tenth line segment and the eighth and twelfth line segments results in equal lengths for the first secondary coupling line 7032a, the second secondary coupling line 7032b, and the primary coupling line 7031. This maximizes the coupling degree and impedance matching effect of the balun.

It should be noted that in the embodiments of this application, each coupling line of the same metal layer is always spaced apart and not connected to each other. The intersection points of different coupling lines presented in the above drawings are intersection points of projections of different coupling lines on a certain plane, rather than intersections of the coupling lines themselves. In fact, near an intersection point of any two coupling lines, one coupling line can jump to another metal layer through a conductive via, cross the intersection point, and then jump back to the originally arranged metal layer to avoid physical connection between the two coupling lines.

In some implementations, as shown in FIG. 12, when the balun 703 has at least two bending segments, if the first segment and the last segment of the balun 703 have the same extension direction, then at each bending segment of the balun 703, the first secondary coupling line 7032a, the second secondary coupling line 7032b, and the primary coupling line 7031 can remain parallel without crossing. In this case, the lengths of each coupling line in the balun 703 are still equal or roughly equal, and the balun 703 still maintains a high coupling degree.

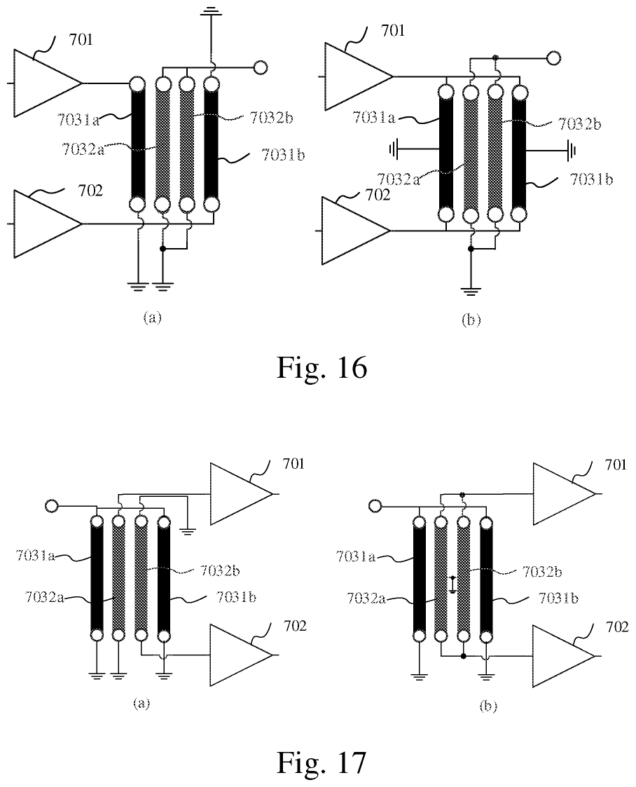

In some embodiments, as shown in FIG. 16 and FIG. 17, the primary coupling line 7031 includes a first primary coupling line 7031a and a second primary coupling line 7031b, and the secondary coupling line 7032 includes a first secondary coupling line 7032a and a second secondary coupling line 7032b. Both the first secondary coupling line 7032a and the second secondary coupling line 7032b are arranged between the first primary coupling line 7031a and the second primary coupling line 7031b to strengthen the coupling degree between the primary and secondary coupling lines.

As an implementation, when the balun 703 serves as an output balun of the power amplifier, optionally, the first primary coupling line 7031a and the second primary coupling line 7031b can be connected in series or in parallel between the output terminal of the first power amplification circuit 701 and the output terminal of the second power amplification circuit 702. Exemplarily, the first primary coupling line 7031a and the second primary coupling line 7031b can be connected in series between the output terminal of the first power amplification circuit 701 and the output terminal of the second power amplification circuit 702 as shown in (a) of FIG. 16, or can be connected in parallel between the output terminal of the first power amplification circuit 701 and the output terminal of the second power amplification circuit 702 as shown in (b) of FIG. 16. At this time, the first secondary coupling line 7032a and the second secondary coupling line 7032b can be connected in parallel. One end of the parallel secondary coupling lines is used to connect to a signal transmission terminal to send an amplified RF signal to the signal transmission terminal, and the other end is grounded. In this implementation, the balun 703 is a balanced-to-unbalanced balun, and its function can refer to the relevant descriptions of the preceding embodiments and is not repeated here.

As an implementation, when the balun 703 serves as an input balun or an inter-stage matching balun of the power amplifier, optionally, the first secondary coupling line 7032a and the second secondary coupling line 7032b can be connected in series or in parallel between the input terminal of the first power amplification circuit 701 and the input terminal of the second power amplification circuit 702. Exemplarily, the first secondary coupling line 7032a and the second secondary coupling line 7032b can be connected in series between the input terminal of the first power amplification circuit 701 and the input terminal of the second power amplification circuit 702 as shown in (a) of FIG. 17, or can be connected in parallel between the input terminal of the first power amplification circuit 701 and the input terminal of the second power amplification circuit 702 as shown in (b) of FIG. 17. At this time, the first primary coupling line 7031a and the second primary coupling line 7031b can be connected in parallel. One end of the parallel primary coupling lines is used to receive a single-ended RF input signal, and the other end is grounded. In this implementation, the balun 703 is an unbalanced-to-balanced balun, and its function can refer to the relevant descriptions of the preceding embodiments and is not repeated here.

In at least one embodiment, the primary coupling line and the secondary coupling line can respectively be formed by multiple coupling lines connected in parallel, and the primary and secondary coupling lines are interleaved in the same metal layer to further increase a coupling area and improve the coupling degree of the transformer structure.

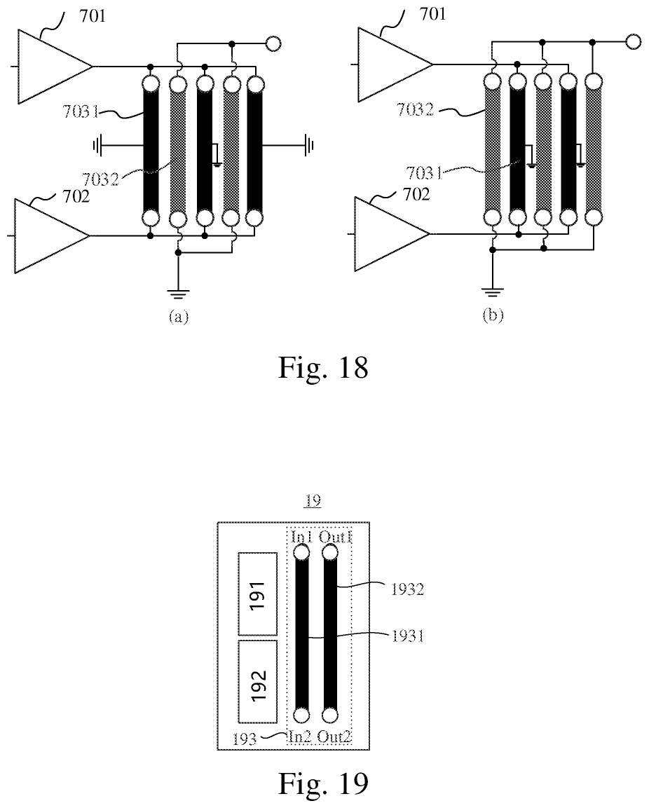

Optionally, when both the number of primary coupling lines and the number of secondary coupling lines are multiple and the lines are located in a same plane, as shown in FIG. 18, to ensure balance of the transformer structure, the coupling lines on both sides can be of the same type. For example, if both sides are primary coupling lines or both sides are secondary coupling lines, the difference between the number of primary coupling lines and the number of secondary coupling lines needs to be 1. Exemplarily, the transformer structure can include N primary coupling lines and M secondary coupling lines, and the N primary coupling lines and the M secondary coupling lines are interleaved; both N and M are positive integers, and N=M+1 or N=M−1. For instance, when there is one more primary coupling line than secondary coupling lines (N=M+1), the primary and secondary coupling lines are interleaved in an order of primary→secondary . . . →primary. When there is one more secondary coupling line than primary coupling lines (N=M−1), the primary and secondary coupling lines are interleaved in an order of secondary→primary . . . →secondary. In this way, the balance of the transformer structure is ensured while enhancing its coupling degree.

As an implementation, the balun 703 and both the first power amplification circuit 701 and the second power amplification circuit 702 are integrated in a chip. Exemplarily, the first primary coupling line 7031a, the second primary coupling line 7031b, the first secondary coupling line 7032a, and the second secondary coupling line 7032b can all be arranged in a straight-line shape. Compared to a case with only one primary coupling line and one secondary coupling line, the four coupling lines increase the overall width of the balun, making the length and width of the chip closer to each other when integrated. For example, the first power amplification circuit 701 and the second power amplification circuit 702 can be arranged on the same side of the straight-line balun 703. The first power amplification circuit 701 and the second power amplification circuit 702 respectively include multiple parallel amplification transistors, and the multiple transistors in each power amplification circuit can be arranged in an array along the extension direction of the coupling lines of the balun 703. In this case, when the first power amplification circuit 701, the second power amplification circuit 702, and the balun 703 are integrated in the chip, the difference between the chip's length and width is small. This prevents the chip from forming a long strip structure due to an excessively long balun, reduces the risk of chip breakage, and is more aesthetic.

The amplification transistors in the first power amplification circuit 701 and the second power amplification circuit 702 can be Metal-Oxide-Semiconductor (MOS) field-effect transistors or Heterojunction Bipolar Transistors (HBTs).

In the above embodiments, the first power amplification circuit 701 and the second power amplification circuit 702 can be integrated in the chip. Optionally, the balun 703 can be integrated in the chip with the first power amplification circuit 701 and the second power amplification circuit 702, or it can be disposed outside the chip and connected to the chip.

The embodiments of this application further provide a chip. As shown in FIG. 19, the chip 19 includes at least one power amplifier. The power amplifier includes a first power amplification circuit 191, a second power amplification circuit 192, and a balun 193. The first power amplification circuit 191 and the second power amplification circuit 192 are respectively connected to the balun 193. The balun 193 includes a primary coupling line 1931 and a secondary coupling line 1932. The primary coupling line 1931 includes a first input terminal and a second input terminal, and the secondary coupling line 1932 includes a first output terminal and a second output terminal. A first routing path of the primary coupling line follows a second routing path of the secondary coupling line. The first routing path is a routing path from the first input terminal to the second input terminal, and the second routing path is a routing path from the first output terminal to the second output terminal.

In the embodiments of this application, since the paths of the primary coupling line 1931 and the secondary coupling line 1932 from the starting point to the ending point follow each other, every segment of the primary coupling line 1931 can couple with a corresponding segment of the secondary coupling line 1932. Conversely, every segment of the secondary coupling line 1932 can also couple with a corresponding segment of the primary coupling line 1931, providing a better coupling degree compared to the structure shown in FIG. 1.

In some embodiments, the balun 193 can adopt the same structure as the transformer structure 20 of any of the preceding embodiments, such as being arranged in a straight-line shape, a broken-line shape, an arc-shape, a U-shape, or an L-shape. For specific details, reference can be made to the descriptions of the preceding embodiments, and details are not repeated here. In some embodiments, the power amplifier can adopt the same or similar implementation manner as the power amplifier 70 of any of the preceding embodiments, and details are not repeated here.

In some embodiments, the first power amplification circuit 191 includes multiple parallel first amplification transistors, and the second power amplification circuit includes multiple parallel second amplification transistors. Both the primary coupling line and the secondary coupling line are arranged in a straight-line shape. The multiple first amplification transistors and the multiple second amplification transistors are arranged side-by-side on one side of the balun along an extension direction of the primary coupling line and the secondary coupling line.

Optionally, the first amplification transistors and the second amplification transistors can be MOS (Metal-Oxide-Semiconductor) field-effect transistors or HBTs (Heterojunction Bipolar Transistors). As an implementation, the power amplifier can be a differential power amplification circuit, and the first amplification transistors and the second amplification transistors are transistors of opposite types. For example, the first amplification transistor is a P-type MOS tube/PNP-type HBT, and the second amplification transistor is an N-type MOS tube/NPN-type HBT; or, the first amplification transistor is an N-type MOS tube/NPN-type HBT, and the second amplification transistor is a P-type MOS tube/PNP-type HBT.

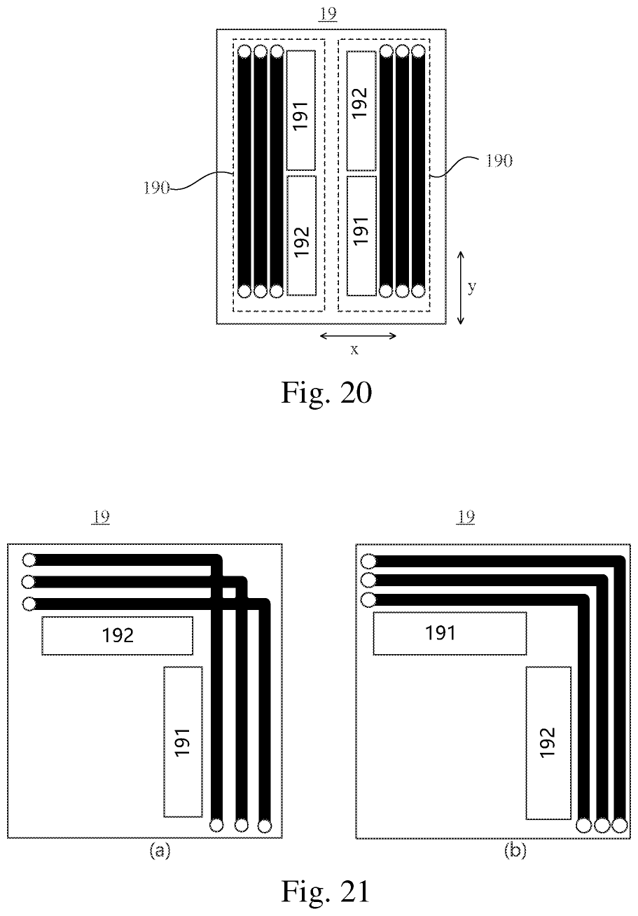

In some embodiments, as shown in FIG. 20, the chip 19 includes at least two power amplifiers 190. The power amplifiers are arranged side-by-side along a preset arrangement direction (x-direction), and the balun in each power amplifier extends along a same direction (y-direction). The arrangement direction of the power amplifiers (x-direction) is perpendicular to the extension direction of any of the baluns (y-direction). Thus, when the lengths of the primary and secondary coupling lines are long, the length and width of the chip become closer by arranging multiple power amplifiers side-by-side. This prevents the chip from forming a long strip structure due to an excessively long balun, reduces the risk of chip breakage, and is more aesthetic.

In some embodiments, as shown in FIG. 21(a) and FIG. 21(b), both the primary coupling line and the secondary coupling line are arranged in an L-shape. The first power amplification circuit 191 includes multiple parallel first amplification transistors, which are arranged side-by-side along one side of the L-shape. The second power amplification circuit 192 includes multiple parallel second amplification transistors, which are arranged side-by-side along the other side of the L-shape. Optionally, the first power amplification circuit 191 and the second power amplification circuit 192 can be arranged on the inner side of the balun to reasonably utilize the space on the inner side of the L-shaped structure, making the overall layout of the chip more compact with a smaller area.

In the embodiments of this application, by arranging the primary and secondary coupling lines in an L-shape, the line length of each coupling line can be increased compared to the straight-line shape, thereby achieving a larger inductance and suiting scenarios with higher inductance requirements. Furthermore, the L-shaped balun can extend along the edge of the chip to save internal space for other circuit layouts.

In some embodiments, the chip includes at least one metal layer. When each of the primary coupling line and the secondary coupling line is provided as a single line, they can be located in a same metal layer. When there are multiple primary coupling lines or secondary coupling lines, at least one primary coupling line and at least one secondary coupling line can be located in a same metal layer. Arranging at least one primary coupling line and at least one secondary coupling line in the same layer can reduce the number of metal layers occupied by the balun, simplify the chip manufacturing process, and decrease costs.

As an implementation, the chip includes a first metal layer and a second metal layer, each provided with two primary coupling lines and one secondary coupling line. Taking the balun as an output balun of the power amplifier as an example, the two primary coupling lines in the same metal layer are respectively connected to different power amplification circuits and couple with the secondary coupling line located in the same metal layer. For example, the primary coupling lines include a first primary coupling line and a second primary coupling line arranged in the first metal layer, and further include a third primary coupling line and a fourth primary coupling line arranged in the second metal layer. The secondary coupling lines include a first secondary coupling line arranged in the first metal layer and a second secondary coupling line arranged in the second metal layer. The first and second primary coupling lines respectively couple with the first secondary coupling line, and the third and fourth primary coupling lines respectively couple with the second secondary coupling line. Furthermore, both the first and third primary coupling lines are connected to the first power amplification circuit, and both the second and fourth primary coupling lines are connected to the second power amplification circuit. Optionally, a length of the first primary coupling line is equal to a length of the fourth primary coupling line, and a length of the second primary coupling line is equal to a length of the third primary coupling line. In this way, the sum of the first and third primary coupling lines is equal to the sum of the second and fourth primary coupling lines. That is, a total length of the primary coupling lines connected to the first power amplification circuit is equal to a total length of the primary coupling lines connected to the second power amplification circuit. Thus, even if the lengths of the first and second primary coupling lines located in the same metal layer are different, the power amplifier can maintain good balance. In other words, when the balun has one or more bending segments, the two primary coupling lines and one secondary coupling line located in the same metal layer do not need to cross at the bends to maintain equal lengths, thereby avoiding losses caused by the crossing of coupling lines and improving the efficiency of the power amplifier.

As an implementation, the chip includes a first metal layer and a second metal layer, each provided with one primary coupling line and two secondary coupling lines. Taking the balun as an input balun of the power amplifier as an example, the two secondary coupling lines in the same metal layer are respectively connected to different power amplification circuits and couple with the primary coupling line located in the same metal layer. For example, the secondary coupling lines include a first secondary coupling line and a second secondary coupling line arranged in the first metal layer, and further include a third secondary coupling line and a fourth secondary coupling line arranged in the second metal layer. The primary coupling lines include a first primary coupling line arranged in the first metal layer and a second primary coupling line arranged in the second metal layer. The first and second secondary coupling lines respectively couple with the first primary coupling line, and the third and fourth secondary coupling lines respectively couple with the second primary coupling line. Furthermore, both the first and third secondary coupling lines are connected to the first power amplification circuit, and both the second and fourth secondary coupling lines are connected to the second power amplification circuit. Optionally, a length of the first secondary coupling line is equal to a length of the fourth secondary coupling line, and a length of the second secondary coupling line is equal to a length of the third secondary coupling line. In this way, the sum of the first and third secondary coupling lines is equal to the sum of the second and fourth secondary coupling lines. That is, a total length of the secondary coupling lines connected to the first power amplification circuit is equal to a total length of the secondary coupling lines connected to the second power amplification circuit. Thus, even if the lengths of the first and second secondary coupling lines located in the same metal layer are different, the power amplifier can maintain good balance. In other words, when the balun has one or more bending segments, the two secondary coupling lines and one primary coupling line located in the same metal layer do not need to cross at the bends to maintain equal lengths, thereby avoiding losses caused by the crossing of coupling lines and improving the efficiency of the power amplifier.

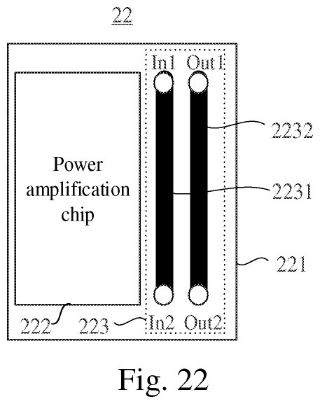

The embodiments of this application further provide an RF front-end module. As shown in FIG. 22, the RF front-end module 22 includes a substrate 221, a power amplification chip 222, and a balun 223. Both the power amplification chip 222 and the balun 223 are disposed on the substrate and can be connected via metal routings on the substrate. The balun 223 includes a primary coupling line 2231 and a secondary coupling line 2232. The primary coupling line 2231 includes a first input terminal In1 and a second input terminal In2; the secondary coupling line 2232 includes a first output terminal Out1 and a second output terminal Out2. A first routing path of the primary coupling line 2231 follows a second routing path of the secondary coupling line 2232. The first routing path is a routing path from the first input terminal In1 to the second input terminal In2, and the second routing path is a routing path from the first output terminal Out1 to the second output terminal Out2.

In the embodiments of this application, since the paths of the primary coupling line 2231 and the secondary coupling line 2232 from the starting point to the ending point follow each other, every segment of the primary coupling line can couple with a corresponding segment of the secondary coupling line. Conversely, every segment of the secondary coupling line can also couple with a corresponding segment of the primary coupling line, providing a better coupling degree compared to the structure shown in FIG. 1.

In some embodiments, the balun 223 can adopt the same structure as the transformer structure 20 of any of the preceding embodiments, such as being arranged in a straight-line shape, a broken-line shape, an arc-shape, a U-shape, or an L-shape. For specific details, reference can be made to the descriptions of the preceding embodiments, and details are not repeated here. Optionally, the balun 223 can be an output balun, an input balun, or an inter-stage matching balun of the power amplification chip 222.

In some embodiments, a first power amplification circuit 2221 and a second power amplification circuit 2222 are integrated in the power amplification chip 222. An output terminal of the first power amplification circuit 2221 and an output terminal of the second power amplification circuit 2222 are respectively connected to the primary coupling line 2231 of the balun 223, and the secondary coupling line 2232 of the balun is connected to a signal transmission terminal. In this case, the balun 223 serves as an output balun of the power amplification chip 222 and can transform differential RF signals output by the power amplification chip 222 into an unbalanced RF signal to facilitate processing by a subsequent-stage circuit. Moreover, it matches the output impedance of the power amplification chip with the input impedance of the subsequent-stage circuit, thereby reducing the loss of RF signals during transmission.

In some embodiments, a first power amplification circuit 2221 and a second power amplification circuit 2222 are integrated in the power amplification chip 222. An input terminal of the first power amplification circuit 2221 and an input terminal of the second power amplification circuit 2222 are respectively connected to the secondary coupling line 2232 of the balun, and the primary coupling line 2231 of the balun is used to receive an RF input signal. In this case, the balun 223 can serve as an input balun or an inter-stage matching balun of the power amplification chip 222 and can transform a single-ended RF signal received from a previous-stage circuit into differential RF signals to facilitate amplification by a differential power amplification circuit in the power amplification chip 222. Moreover, it matches the output impedance of the previous-stage circuit with the input impedance of the subsequent-stage differential power amplification circuit, thereby reducing the loss of RF signals during transmission.

Optionally, the overall shape of the balun 223 can be a strip shape, a broken-line shape, a U-shape, a C-shape, an L-shape, or other shapes to facilitate connection with the power amplification chip 222 or to make the layout of the balun 223 and the power amplification chip 222 more compact, thereby reducing the area occupied by the RF front-end module.

Exemplarily, when a required inductance is small, the balun 223 can present as a strip shape and be arranged on one side of the power amplification chip 222.

Exemplarily, when a required inductance is large, the balun 223 can present as a C-shape, a U-shape, an L-shape, or a broken-line shape and be arranged surrounding the power amplification chip 222. That is, the power amplification chip 222 can be arranged in an internal space formed by the C-shape, U-shape, or L-shape to make the layout of the balun 223 and the power amplification chip 222 more compact.

Exemplarily, when the balun 223 serves as the output balun of the power amplification chip 222, and other circuit devices further need to be laid out between the output end of the power amplification chip 222 and a subsequent-stage circuit (such as an RF switch) of the balun 223, the balun 223 can have a broken-line shape or an irregular line-shaped structure to avoid other circuit devices on the substrate.

In the embodiments of this application, the shape and arrangement position of the balun 223 can be flexibly set to adapt to the layout of the power amplification chip 222 and other circuits on the substrate. This makes the overall structure of the RF front-end module more compact and facilitates its miniaturization design.

In some embodiments, the substrate includes at least one metal layer. When each of the primary coupling line and the secondary coupling line is provided as a single line, they can be located in a same metal layer. When there are multiple primary coupling lines or secondary coupling lines, at least one primary coupling line and at least one secondary coupling line can be located in a same metal layer. Arranging at least one primary coupling line and at least one secondary coupling line in the same layer can reduce the number of metal layers occupied by the balun, simplify the manufacturing process of the RF front-end module, and decrease costs.

As an implementation, the substrate includes a first metal layer and a second metal layer, each provided with two primary coupling lines and one secondary coupling line. Taking the balun as an output balun of the power amplifier as an example, the two primary coupling lines in the same metal layer are respectively connected to different power amplification circuits and couple with the secondary coupling line located in the same metal layer. For example, the primary coupling lines include a first primary coupling line and a second primary coupling line arranged in the first metal layer, and further include a third primary coupling line and a fourth primary coupling line arranged in the second metal layer. The secondary coupling lines include a first secondary coupling line arranged in the first metal layer and a second secondary coupling line arranged in the second metal layer. The first and second primary coupling lines respectively couple with the first secondary coupling line, and the third and fourth primary coupling lines respectively couple with the second secondary coupling line. Furthermore, both the first and third primary coupling lines are connected to the first power amplification circuit, and both the second and fourth primary coupling lines are connected to the second power amplification circuit. Optionally, a length of the first primary coupling line is equal to a length of the fourth primary coupling line, and a length of the second primary coupling line is equal to a length of the third primary coupling line. In this way, the sum of the first and third primary coupling lines is equal to the sum of the second and fourth primary coupling lines. That is, a total length of the primary coupling lines connected to the first power amplification circuit is equal to a total length of the primary coupling lines connected to the second power amplification circuit. Thus, even if the lengths of the first and second primary coupling lines located in the same metal layer are different, the power amplifier can maintain good balance. In other words, when the balun has one or more bending segments, the two primary coupling lines and one secondary coupling line located in the same metal layer do not need to cross at the bends to maintain equal lengths, thereby avoiding losses caused by the crossing of coupling lines and improving the efficiency of the power amplifier.

As an implementation, the substrate includes a first metal layer and a second metal layer, each provided with one primary coupling line and two secondary coupling lines. Taking the balun as an input balun of the power amplifier as an example, the two secondary coupling lines in the same metal layer are respectively connected to different power amplification circuits and couple with the primary coupling line located in the same metal layer. For example, the secondary coupling lines include a first secondary coupling line and a second secondary coupling line arranged in the first metal layer, and further include a third secondary coupling line and a fourth secondary coupling line arranged in the second metal layer. The primary coupling lines include a first primary coupling line arranged in the first metal layer and a second primary coupling line arranged in the second metal layer. The first and second secondary coupling lines respectively couple with the first primary coupling line, and the third and fourth secondary coupling lines respectively couple with the second primary coupling line. Furthermore, both the first and third secondary coupling lines are connected to the first power amplification circuit, and both the second and fourth secondary coupling lines are connected to the second power amplification circuit. Optionally, a length of the first secondary coupling line is equal to a length of the fourth secondary coupling line, and a length of the second secondary coupling line is equal to a length of the third secondary coupling line. In this way, the sum of the first and third secondary coupling lines is equal to the sum of the second and fourth secondary coupling lines. That is, a total length of the secondary coupling lines connected to the first power amplification circuit is equal to a total length of the secondary coupling lines connected to the second power amplification circuit. Thus, even if the lengths of the first and second secondary coupling lines located in the same metal layer are different, the power amplifier can maintain good balance. In other words, when the balun has one or more bending segments, the two secondary coupling lines and one primary coupling line located in the same metal layer do not need to cross at the bends to maintain equal lengths, thereby avoiding losses caused by the crossing of coupling lines and improving the efficiency of the power amplifier.

The above embodiments are only used to illustrate the technical solutions of this application rather than to limit them. Although this application has been described in detail with reference to the preceding embodiments, those skilled in the art should understand that modifications can still be made to the technical solutions recorded in the preceding embodiments, or equivalent substitutions can be made to some technical features thereof. Such modifications or substitutions do not cause the essence of the corresponding technical solutions to depart from the spirit and scope of the technical solutions in the embodiments of this application.

What is claimed is:

1. A power amplifier, comprising a first power amplification circuit, a second power amplification circuit, and a balun, wherein the first power amplification circuit and the second power amplification circuit are respectively connected to the balun;
the balun comprises:
a primary coupling line, the primary coupling line comprising a first input terminal and a second input terminal; and
a secondary coupling line, the secondary coupling line comprising a first output terminal and a second output terminal;
wherein a first routing path of the primary coupling line follows a second routing path of the secondary coupling line, the first routing path being a routing path from the first input terminal to the second input terminal, and the second routing path being a routing path from the first output terminal to the second output terminal.

2. The power amplifier of claim 1, wherein the primary coupling line comprises a first primary coupling line and a second primary coupling line, and the secondary coupling line is disposed between the first primary coupling line and the second primary coupling line.

3. The power amplifier of claim 2, wherein the balun comprises an odd number of bending segments, at the bending segment, the first primary coupling line comprises a first line segment and a second line segment connected at a first angle, the secondary coupling line comprises a third line segment and a fourth line segment connected at the first angle, and the second primary coupling line comprises a fifth line segment and a sixth line segment connected at the first angle, wherein at the odd number of bending segments:
the first line segment, the third line segment, and the fifth line segment are sequentially arranged in parallel and have lengths that sequentially increase; and
the second line segment, the fourth line segment, and the sixth line segment are sequentially arranged in parallel and have lengths that sequentially decrease.

4. The power amplifier of claim 3, wherein a length difference between the third line segment and the first line segment, a length difference between the fifth line segment and the third line segment, a length difference between the second line segment and the fourth line segment, and a length difference between the fourth line segment and the sixth line segment are all a first value.

5. The power amplifier of claim 2, wherein lengths of the first primary coupling line, the second primary coupling line, and the secondary coupling line are the same.

6. The power amplifier of claim 2, wherein
a first input terminal of the first primary coupling line and a first input terminal of the second primary coupling line are respectively connected to an output terminal of the first power amplification circuit, and a second input terminal of the first primary coupling line and a second input terminal of the second primary coupling line are respectively connected to an output terminal of the second power amplification circuit;
the first output terminal of the secondary coupling line is configured to be connected to a signal transmission terminal, and the second output terminal of the secondary coupling line is configured to be grounded;
a first input terminal of the first primary coupling line is configured to be connected to an output terminal of the first power amplification circuit, and a second input terminal of the first primary coupling line is configured to be grounded;
a first input terminal of the second primary coupling line is configured to be grounded, and a second input terminal of the second primary coupling line is configured to be connected to an output terminal of the second power amplification circuit; and
the first output terminal of the secondary coupling line is configured to be connected to a signal transmission terminal, and the second output terminal of the secondary coupling line is configured to be grounded.

7. The power amplifier of claim 2, wherein a first input terminal of the first primary coupling line and a first input terminal of the second primary coupling line are respectively configured to receive an RF input signal, and a second input terminal of the first primary coupling line and a second input terminal of the second primary coupling line are respectively configured to be grounded; and
the first output terminal of the secondary coupling line is connected to an input terminal of the first power amplification circuit, and the second output terminal of the secondary coupling line is connected to an input terminal of the second power amplification circuit.

8. The power amplifier of claim 1, wherein the balun comprises N of the primary coupling lines and M of the secondary coupling lines, and the N primary coupling lines and the M secondary coupling lines are interleaved on a same metal layer; wherein both N and M are positive integers, and N=M+1 or N=M−1.

9. The power amplifier of claim 1, wherein the secondary coupling line comprises a first secondary coupling line and a second secondary coupling line, and the primary coupling line is disposed between the first secondary coupling line and the second secondary coupling line.

10. The power amplifier of claim 9, wherein the balun comprises an odd number of bending segments, at the bending segment, the first secondary coupling line comprises a seventh line segment and an eighth line segment connected at a second angle, the primary coupling line comprises a ninth line segment and a tenth line segment connected at the second angle, and the second secondary coupling line comprises an eleventh line segment and a twelfth line segment connected at the second angle, wherein at the odd number of bending segments:
the seventh line segment, the ninth line segment, and the eleventh line segment are parallel to each other and have lengths that sequentially increase; and
the eighth line segment, the tenth line segment, and the twelfth line segment are parallel to each other and have lengths that sequentially decrease.

11. The power amplifier of claim 10, wherein a length difference between the ninth line segment and the seventh line segment is equal to a length difference between the eleventh line segment and the ninth line segment, and a length difference between the eighth line segment and the tenth line segment is equal to a length difference between the tenth line segment and the twelfth line segment.

12. The power amplifier of claim 9, wherein the first input terminal of the primary coupling line is connected to an output terminal of the first power amplification circuit, and the second input terminal of the primary coupling line is connected to an output terminal of the second power amplification circuit; and
a first output terminal of the first secondary coupling line and a first output terminal of the second secondary coupling line are respectively configured to be connected to a signal transmission terminal, and a second output terminal of the first secondary coupling line and a second output terminal of the second secondary coupling line are respectively configured to be grounded.

13. The power amplifier of claim 9, wherein
the first input terminal of the primary coupling line is configured to receive an RF input signal, and the second input terminal of the primary coupling line is configured to be grounded;
a first output terminal of the first secondary coupling line and a first output terminal of the second secondary coupling line are respectively connected to an input terminal of a first power amplifier, and a second output terminal of the first secondary coupling line and a second output terminal of the second secondary coupling line are respectively connected to an input terminal of a second power amplifier;
the first input terminal of the primary coupling line is configured to receive an RF input signal, and the second input terminal of the primary coupling line is configured to be grounded;
a first output terminal of the first secondary coupling line is connected to an input terminal of the first power amplification circuit, and a second output terminal of the first secondary coupling line is configured to be grounded; and
a first output terminal of the second secondary coupling line is configured to be grounded, and a second output terminal of the second secondary coupling line is connected to an input terminal of the second power amplification circuit.

14. A chip, comprising at least one power amplifier, wherein the power amplifier comprises a first power amplification circuit, a second power amplification circuit, and a balun, and the first power amplification circuit and the second power amplification circuit are respectively connected to the balun;
the balun comprises:
a primary coupling line, the primary coupling line comprising a first input terminal and a second input terminal; and
a secondary coupling line, the secondary coupling line comprising a first output terminal and a second output terminal;
wherein a first routing path of the primary coupling line follows a second routing path of the secondary coupling line, the first routing path being a routing path from the first input terminal to the second input terminal, and the second routing path being a routing path from the first output terminal to the second output terminal.

15. The chip of claim 14, wherein the first power amplification circuit comprises a plurality of first amplification transistors connected in parallel, and the second power amplification circuit comprises a plurality of second amplification transistors connected in parallel;
the primary coupling line and the secondary coupling line are both arranged in the straight-line shape, and the plurality of first amplification transistors and the plurality of second amplification transistors are arranged side-by-side on one side of the balun along an extension direction of the primary coupling line and the secondary coupling line.

16. The chip of claim 15, wherein the chip comprises at least two of the power amplifiers, the power amplifiers are arranged side-by-side along a preset arrangement direction, and the balun in each of the power amplifiers extends along a same direction, wherein the arrangement direction is perpendicular to the extension direction of any one of the baluns.

17. The chip of claim 14, wherein the chip comprises at least one metal layer, and the primary coupling line and the secondary coupling line are located in a same metal layer; or, when the primary coupling line or the secondary coupling line comprises a plurality of lines, at least one of the primary coupling lines and at least one of the secondary coupling lines are located in a same metal layer.

18. An RF front-end module, comprising a substrate, a power amplification chip disposed on the substrate, and a balun disposed on the substrate and connected to the power amplification chip; wherein
the balun comprises:
a primary coupling line, the primary coupling line comprising a first input terminal and a second input terminal; and
a secondary coupling line, the secondary coupling line comprising a first output terminal and a second output terminal;
wherein a first routing path of the primary coupling line follows a second routing path of the secondary coupling line, the first routing path being a routing path from the first input terminal to the second input terminal, and the second routing path being a routing path from the first output terminal to the second output terminal.

19. The RF front-end module of claim 18, wherein
a first power amplification circuit and a second power amplification circuit are integrated in the power amplification chip;
an output terminal of the first power amplification circuit and an output terminal of the second power amplification circuit are respectively connected to the primary coupling line of the balun, and the secondary coupling line of the balun is connected to a signal transmission terminal;
a first power amplification circuit and a second power amplification circuit are integrated in the power amplification chip; and
an output terminal of the first power amplification circuit and an output terminal of the second power amplification circuit are respectively connected to the secondary coupling line of the balun, and the primary coupling line of the balun is configured to receive an RF input signal.

20. The RF front-end module of claim 18, wherein the substrate comprises at least one metal layer, and the primary coupling line and the secondary coupling line are located in a same metal layer; or, when the primary coupling line or the secondary coupling line comprises a plurality of lines, at least one of the primary coupling lines and at least one of the secondary coupling lines are located in a same metal layer.
